(19) United States
(12) Patent Application Publication
(10) Pub. No.: US 2025/0056787 A1
(43) Pub. Date: Feb. 13, 2025

(54) SEMICONDUCTOR DEVICE AND METHOD FOR FABRICATING THE SAME

(71) Applicant: SK hynix Inc., Gyeonggi-do (KR)

(72) Inventors: Seung Hwan KIM, Gyeonggi-do (KR); Seung Cheol LEE, Gyeonggi-do (KR); Hyun Woo JIN, Gyeonggi-do (KR)

(21) Appl. No.: 18/581,402

(22) Filed: Feb. 20, 2024

(30) Foreign Application Priority Data
Aug. 10, 2023 (KR) 10-2023-0104844

(51) Int. Cl. H10B 12/00

(52) U.S. Cl. CPC H10B 12/03; H10B 12/482; H10B 12/488

(57) ABSTRACT

A method for fabricating a semiconductor device includes: forming preliminary horizontal layers vertically stacked over a lower structure in a first direction and extending horizontally in a second direction crossing the first direction; forming trimming target layers that surround each of the preliminary horizontal layers; forming horizontal layers by trimming the preliminary horizontal layers in a third direction crossing the second direction; forming trimmed target layers by trimming the trimming target layers in the third direction; and replacing the trimmed target layers with conductive layers.

### CROSS-REFERENCE TO RELATED APPLICATIONS

The present application claims priority under 35 U.S.C. 119 (a) to Korean Patent Application No. 10-2023-0104844, filed on Aug. 10, 2023, which is incorporated herein by reference in its entirety.

### BACKGROUND

### 1. Field

Various embodiments of the present invention relate to a semiconductor device, and more particularly, to a semiconductor device including three-dimensional memory cells, and a method for fabricating the same.

### 2. Description of the Related Art

Recently, in order to cope with the demands for large capacity and miniaturization of memory devices, a technology for providing a 3D memory device in which a plurality of memory cells are stacked has been proposed.

### SUMMARY

Embodiments of the present invention are directed to a three-dimensional semiconductor device including highly integrated memory cells arranged in a three-dimensional array, and a method for fabricating the semiconductor device. The three-dimensional semiconductor device may be referred to hereinafter also simply as a semiconductor device.

In accordance with an embodiment of the present invention, a method for fabricating a semiconductor device includes: forming preliminary horizontal layers vertically stacked over a lower structure in a first direction, each preliminary horizontal layer extending in a second direction crossing the first direction; forming trimming target layers that surround each of the preliminary horizontal layers; forming horizontal layers by trimming the preliminary horizontal layers in a third direction crossing the second direction; forming trimmed target layers by trimming the trimming target layers in the third direction; and replacing the trimmed target layers with conductive layers.

In accordance with another embodiment of the present invention, a method for fabricating a semiconductor device includes: forming preliminary horizontal layers vertically stacked over a lower structure in a first direction and extending horizontally in a second direction crossing the first direction; forming conductive target layers disposed in upper and lower portions of each of the preliminary horizontal layers; forming horizontal layers by trimming the preliminary horizontal layers in a third direction crossing the second direction; forming a trimmed conductive target layer by trimming the conductive target layers in the third direction; and forming a pair of horizontal conductive lines respectively disposed on upper and lower surfaces of the horizontal layers by horizontally recessing edge portions on both sides of the trimmed conductive target layer in the second direction.

In accordance with another embodiment of the present invention, a semiconductor device includes: cell separation layers vertically oriented in a first direction; horizontal layers oriented horizontally in a second direction crossing the first direction and vertically stacked in the first direction between the cell separation layers; a vertical conductive line oriented vertically in the first direction and coupled to first edges of the horizontal layers; horizontal conductive lines crossing each of the horizontal layers in a third direction crossing the first and second directions; and data storage elements respectively coupled to the second edges of the horizontal layers.

### BRIEF DESCRIPTION OF THE DRAWINGS

FIG. 1A is a schematic perspective view illustrating a memory cell in accordance with an embodiment of the present invention.

FIG. 1B is a schematic cross-sectional view illustrating the memory cell shown in FIG. 1A.

FIG. 1C is a plan view illustrating a switching element shown in FIG. 1A.

FIG. 1D is a schematic cross-sectional view illustrating a memory cell in accordance with another embodiment of the present invention.

FIG. 2 is a schematic plan view illustrating a semiconductor device in accordance with an embodiment of the present invention.

FIG. 3A is a schematic perspective view illustrating a first memory cell array MCA1 shown in FIG. 2.

FIG. 3B is a cross-sectional view taken along a line A-A′ shown in FIG. 2.

FIG. 3C is a cross-sectional view taken along a line B-B′ shown in FIG. 2.

FIG. 3D is a cross-sectional view taken along a line C-C′ shown in FIG. 2.

FIGS. 4A to 26B illustrate an example of a method for fabricating a semiconductor device in accordance with embodiments of the present invention.

FIGS. 27A to 38B are cross-sectional views illustrating a method for fabricating a semiconductor device in accordance with another embodiment of the present invention.

FIGS. 39A to 39C are cross-sectional views illustrating a method for fabricating a semiconductor device in accordance with another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

The following embodiments of the present invention relates to a three-dimensional memory cell. Memory cell density may be increased and parasitic capacitance may be reduced by vertically stacking memory cells.

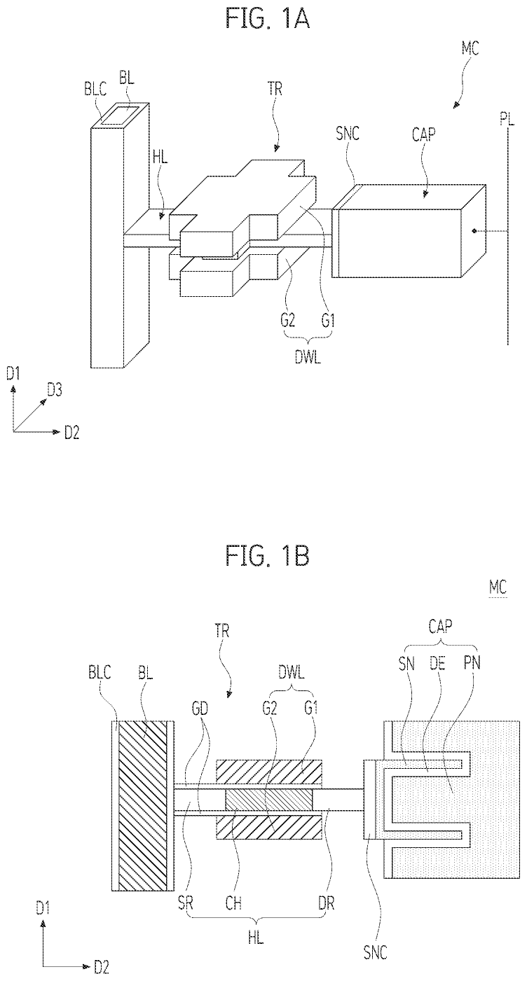

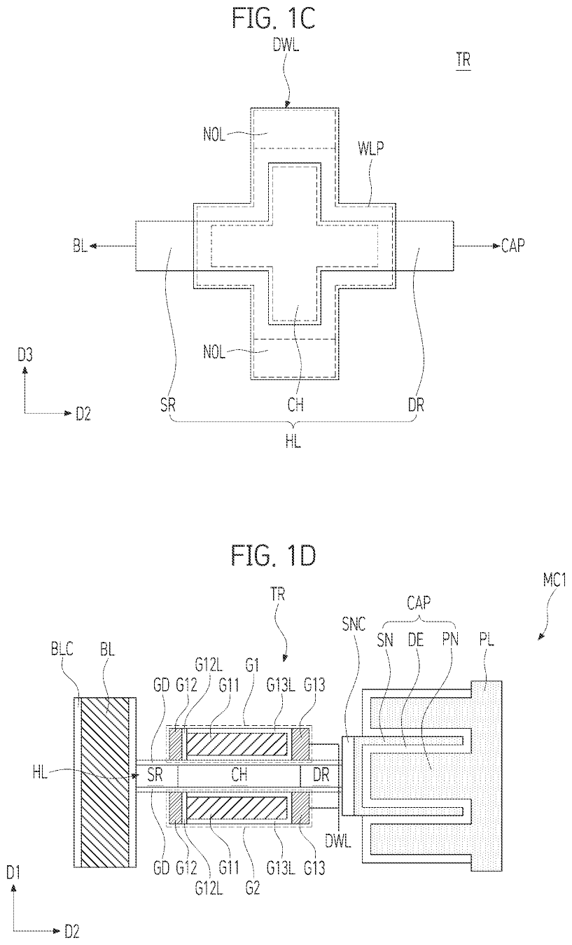

FIG. 1A is a schematic perspective view illustrating a memory cell in accordance with an embodiment of the present invention. FIG. 1B is a schematic cross-sectional view illustrating the memory cell shown in FIG. 1A. FIG. 1C is a plan view illustrating a switching element shown in FIG. 1A.

Referring to FIGS. 1A to 1C, a memory cell MC may include a first conductive line BL, a switching element TR, and a data storage element CAP.

The first conductive line BL may be oriented in a first direction D1. The first direction D1 may also be referred to as the stacking direction or upright direction. In some embodiments, the first direction may be a vertical direction. In some embodiments the first direction may be an upright direction or a vertical direction. It is noted that although certain elements of the invention are described as being vertical or vertically oriented, the invention is not limited thereto. The first conductive line BL may include a bit line. The first conductive line BL may also be referred to as an upright conductive line, a vertical conductive line, a vertically-oriented bit line, a vertically-extending bit line, or a pillar-shaped bit line. The first conductive line BL may include a conductive material. The first conductive line BL may include a silicon-based material, a metal-based material, or a combination thereof. The first conductive line BL may include polysilicon, a metal, a metal nitride, a metal silicide, or a combination thereof. The first conductive line BL may include polysilicon, titanium nitride, tungsten, or a combination thereof. For example, the first conductive line BL may include a stack of titanium nitride and tungsten (TiN/W).

The switching element TR may have a function of controlling voltage (or current) supply to the data storage element CAP in a data write operation and a data read operation of the data storage element CAP. The switching element TR may include a horizontal layer HL, an inter-level dielectric layer GD, and a second conductive line DWL. The horizontal layer HL may in some embodiments be a horizontal layer. The second conductive line DWL may include a horizontal conductive line or a horizontal word line, and the horizontal layer HL may include an active layer. The switching element TR may include a transistor, and in this case, the second conductive line DWL may serve as a gate electrode. The switching element TR may also be referred to as an access element or a selection element. The second conductive line DWL may be referred to as a horizontal gate electrode or a horizontal word line. In some embodiments, the second conductive line DWL may be extending in a horizontal direction and may be referred to as a horizontal gate electrode or a horizontal word line.

The horizontal layer HL may extend in a second direction D2 crossing the first direction D1. The second direction D2 may also be referred to as a horizontal direction D2. In some embodiments the second direction may be a horizontal direction. The second conductive line DWL may extend in a third direction D3 crossing the first and second directions D1 and D2. The third direction D3 may be a second horizontal direction. The second and third directions D2 and D3 may be orthogonal to each other. The first, second, and third direction may be orthogonal to each other. In some embodiments the first direction D1 may be a vertical direction, the second direction D2 may be a first horizontal direction, and the third direction D3 may be a second horizontal direction. For example, the horizontal layer HL may extend in a first horizontal direction (i.e., the second direction D2), and the second conductive line DWL may extend in a second horizontal direction (i.e., the third direction D3).

The horizontal layer HL may include a semiconductor material. For example, the horizontal layer HL may include polysilicon, monocrystalline silicon, germanium, or silicon-germanium. According to another embodiment of the present invention, the horizontal layer HL may include an oxide semiconductor material. For example, the oxide semiconductor material may include indium gallium zinc oxide (IGZO). According to another embodiment of the present invention, the horizontal layer HL may include a conductive metal oxide.

The upper and lower surfaces of the horizontal layer HL may have flat surfaces. The upper and lower surfaces of the horizontal layer HL may be parallel to each other in the second direction D2.

The horizontal layer HL may include a channel CH, a first doped region SR between the channel CH and the first conductive line BL, and a second doped region DR between the channel CH and the data storage element CAP. When the horizontal layer HL is formed of an oxide semiconductor material, the channel CH may be formed of an oxide semiconductor material, and the first and second doped regions SR and DR may be omitted. The horizontal layer HL may also be referred to as an active layer or a thin-body.

The first doped region SR and the second doped region DR may be doped with impurities of the same conductivity type. The first doped region SR and the second doped region DR may be doped with an N-type impurity or a P-type impurity. The first doped region SR and the second doped region DR may include at least one impurity selected among arsenic (As), phosphorus (P), boron (B), indium (In), and combinations thereof. The first doped region SR may be coupled to the first conductive line BL, and the second doped region DR may be coupled to the data storage element CAP. The first and second doped regions SR and DR may be referred to as first and second source/drain regions.

The horizontal layer HL may be horizontally oriented in the second direction D2 from the first conductive line BL.

The second conductive line DWL may have a double structure. For example, the second conductive line DWL may include an upper horizontal line G1 and a lower horizontal line G2 that are facing each other with the horizontal layer HL therebetween. In some embodiments the upper and lower horizontal lines G1 and G2 may be upper and lower horizontal lines G1 and G2. An inter-level dielectric layer GD may be formed over or on the upper and lower surfaces of the horizontal layer HL. The upper horizontal line G1 may be disposed over the horizontal layer HL, and the lower horizontal line G2 may be disposed below the horizontal layer HL. The second conductive line DWL may include a pair of an upper horizontal line G1 and a lower horizontal line G2. In the second conductive line DWL, the same driving voltage may be applied to the upper horizontal line G1 and the lower horizontal line G2. For example, the upper horizontal line G1 and the lower horizontal line G2 may form a pair and may be coupled to one memory cell MC. According to another embodiment of the present invention, different driving voltages may be applied to the upper horizontal line G1 and the lower horizontal line G2. In this case, one between the upper horizontal line G1 and the lower horizontal line G2 may serve as a back gate or a shield gate.

The second conductive line DWL may include a metal-based material, a semiconductor material, or a combination thereof. The second conductive line DWL may include titanium nitride, tungsten, polysilicon, or a combination thereof. For example, the second conductive line DWL may include a TiN/W stack in which titanium nitride and tungsten are sequentially stacked. The second conductive line DWL may include an N-type work function material or a P-type work function material. The N-type work function material may have a low work function of approximately 4.5 eV or less, and the P-type work function material may have a high work function of approximately 4.5 eV or more. The second conductive line DWL may include a stack of a low work function material and a high work function material.

Each of the upper horizontal line G1 and the lower horizontal line G2 may have a width in the second direction D2, for example, the width of the overlapping portion overlapping with the horizontal layer HL, which is greater than the width of a portion that does not overlap with the horizontal layer HL. Due to this difference in width, sidewalls extending in the third direction D3 of the second conductive line DWL may have a notch-shaped sidewall.

Referring back to FIG. 1C, the second conductive line DWL may include a channel overlapping portion WLP and a channel non-overlapping portion NOL. The channel overlapping portion WLP may refer to a portion overlapping with the channel CH of the horizontal layer HL, and the channel non-overlapping portion NOL may refer to a portion that does not overlap with the horizontal layer HL. The channel overlapping portion WLP may have a cross shape or a diamond shape. According to another embodiment of the present invention, the side surfaces of the channel overlapping portion WLP may have a bent shape or a rounded shape.

The channel CH and the channel overlapping portion WLP of the second conductive line DWL may overlap with each other. The channel CH may have a cross shape or a diamond shape. The size of the channel overlapping portion WLP of the second conductive line DWL may be greater than that of the channel CH. The channel overlapping portion WLP of the second conductive line DWL may fully overlap with the channel CH.

From the perspective of a top view, the horizontal layer HL may have a cross shape or a rhombus shape. According to another embodiment of the present invention, side surfaces of the horizontal layer HL may have a bent shape or a rounded shape.

The inter-level dielectric layer GD may be disposed between the horizontal layer HL and the second conductive line DWL. The inter-level dielectric layer GD may be referred to as a gate dielectric layer. The inter-level dielectric layer GD may be referred to as a lateral or horizontal layer side dielectric layer. The inter-level dielectric layer GD may include silicon oxide, silicon nitride, a metal oxide, a metal oxynitride, a metal silicate, a high-k material, a ferroelectric material, an anti-ferroelectric material or a combination thereof. The inter-level dielectric layer GD may include SiO₂, Si₃N₄, HfO₂, Al₂O₃, ZrO₂, AlON, HfON, HfSIO, HfSION, HfZrO, or a combination thereof. The inter-level dielectric layer GD may be formed by thermal oxidation of a semiconductor material.

The data storage element CAP may include a memory element, such as a capacitor. The data storage element CAP may be laterally, for example, horizontally disposed in the second direction D2 from the switching element TR. The data storage element CAP may include a first electrode SN extending laterally, for example, horizontally from the horizontal layer HL in the second direction D2. The data storage element CAP may further include a second electrode PN over the first electrode SN, and a dielectric layer DE between the first electrode SN and the second electrode PN. The first electrode SN, the dielectric layer DE, and the second electrode PN may be laterally, for example, horizontally arranged in the second direction D2. The first electrode SN may include an inner space and a plurality of outer surfaces, and the inner space of the first electrode SN may include a plurality of inner surfaces. The outer surfaces of the first electrode SN may include an upright, e.g., a vertical outer surface and a plurality of lateral, e.g., horizontal outer surfaces. For example, the vertical outer surface of the first electrode SN may extend vertically in the first direction D1, and the horizontal outer surface of the first electrode SN may extend laterally (e.g., horizontally) in the second or third direction D2 or D3. The inner space of the first electrode SN may be a three-dimensional space. The dielectric layer DE may conformally cover or conformally be on the inner and outer surfaces of the first electrode SN. The second electrode PN may be disposed in the inner space of the first electrode SN over the dielectric layer DE. Some of the outer surfaces of the first electrode SN may be electrically connected to the second doped region DR of the horizontal layer HL. The second electrode PN of the data storage element CAP may be coupled to a common plate PL.

The data storage element CAP may have a three-dimensional structure. The first electrode SN may have a 3D structure, and the first electrode SN of the 3D structure may have a lateral, e.g., a horizontal 3D structure which is oriented in the second direction D2. As an example of the 3D structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically connected to the second doped region DR of the horizontal layer HL. A dielectric layer DE and a second electrode PN may be disposed on the cylindrical inner surfaces of the first electrode SN.

According to another embodiment of the present invention, the first electrode SN may have a pillar shape or a pylinder shape. The pylinder shape may refer to a structure in which a pillar shape and a cylindrical shape are merged.

The first electrode SN and the second electrode PN may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode PN may include a combination of a metal-based material and a silicon-based material. For example, the second electrode PN may be a stack of titanium nitride/silicon germanium/tungsten nitride (TIN/SiGe/WN). In the titanium nitride/silicon germanium/tungsten nitride (TiN/SiGe/WN) stack, silicon germanium may be a gap-fill material that fills the inside of the first electrode SN, and titanium nitride (TiN) may serve as the second electrode PN of a data storage element CAP, and tungsten nitride may be a low-resistance material.

The dielectric layer DE may be referred to as a capacitor dielectric layer or a memory layer. The dielectric layer DE may include silicon oxide, silicon nitride, a high-k material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer DE may be formed of a composite layer including two or more layers of the aforementioned high-k materials.

The dielectric layer DE may be formed of zirconium (Zr)-based oxide. The dielectric layer DE may have a stack structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. According to another embodiment of the present invention, the dielectric layer DE may be formed of hafnium (Hf)-based oxide. The dielectric layer DE may have a stack structure including hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, aluminum oxide (Al₂O₃) may have a greater bandgap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a greater bandgap energy than the high-k material. The dielectric layer DE may include silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material. According to another embodiment of the present invention, the dielectric layer DE may include a stacked structure in which a high-k material and a high-bandgap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above stacked structure, aluminum oxide (Al₂O₃) may be thinner than zirconium oxide (ZrO₂) and hafnium oxide (HfO₂).

According to another embodiment of the present invention, the dielectric layer DE may include a high-k material and a high-bandgap material, and may include a laminated structure in which a plurality of high-k materials and a plurality of high-bandgap materials are stacked, or a mixed structure in which a high-k material and a high-bandgap material are inter-mixed with each other.

According to another embodiment of the present invention, the dielectric layer DE may include a ferroelectric material, an anti-ferroelectric material, or a combination thereof. For example, the dielectric layer DE may include hafnium zirconium oxide (HfZrO).

According to another embodiment of the present invention, the dielectric layer DE may include a combination of a high-k material and a ferroelectric material, a combination of a high-k material and an anti-ferroelectric material, a high-k material, or a combination of a ferroelectric material and an anti-ferroelectric material.

According to another embodiment of the present invention, an interface control layer for improving leakage current may be further formed between the first electrode SN and the dielectric layer DE. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with other data storage materials. For example, the data storage material may be a thyristor, a phase change material, a magnetic tunnel junction (MTJ), or a variable resistance material.

For example, the memory cell MC may include a thyristor, the first conductive line BL may be a cathode line, and the data storage element CAP may be replaced with an anode line. The horizontal layer HL may include four semiconductor layers that are laterally stacked in the second direction D2. The thyristor may include a first diode and a second diode that are coupled serially. When a forward bias of the same voltage is applied to the thyristor, the thyristor may have a high conductance state in which a large amount of current flows or a low conductance state in which a small amount of or no current flows. Each memory cell MC may have a ‘1’ state or a ‘0’ state based on the high conductance state and the low conductance state of the thyristor.

Referring back to FIGS. 1A and 1B, the memory cell MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon, and each of the first doped region SR and the second doped region DR may include impurities diffused from the first and second contact nodes BLC and SNC.

FIG. 1D is a schematic cross-sectional view illustrating a memory cell in accordance with another embodiment of the present invention. The memory cell MC1 shown in FIG. 1D may be similar to the memory cell MC shown in FIGS. 1A to 1C. Hereinafter, detailed description on the constituent elements also appearing in FIGS. 1A to 1C may be omitted.

The memory cell MC1 may include a first conductive line BL, a switching element TR, and a data storage element CAP. The switching element TR may include a horizontal layer HL, an inter-level dielectric layer GD, and a second conductive line DWL. The horizontal layer HL may include a first doped region SR, a second doped region DR, and a channel CH. The data storage element CAP may include a first electrode SN, a second electrode PN, and a dielectric layer DE.

The memory cell MC1 may further include a first contact node BLC between the first conductive line BL and the horizontal layer HL, and a second contact node SNC between the horizontal layer HL and the data storage element CAP. The first and second contact nodes BLC and SNC may include doped polysilicon. Each of the first doped region SR and the second doped region DR may include impurities diffused from the first and second contact nodes BLC and SNC.

The second conductive line DWL may include an upper horizontal line G1 and a lower horizontal line G2. Each of the upper horizontal line G1 and the lower horizontal line G2 may include a first work function electrode G11, a second work function electrode G12, and a third work function electrode G13. The second work function electrode G12, the first work function electrode G11, and the third work function electrode G13 may be laterally, e.g., horizontally disposed in the second direction D2. The first work function electrode G11, the second work function electrode G12, and the third work function electrode G13 may directly contact each other. The second work function electrode G12 may be disposed adjacent to the first conductive line BL, and the third work function electrode G13 may be disposed adjacent to the data storage element CAP. The first work function electrode G11 may be disposed between the second work function electrode G12 and the third work function electrode G13. The horizontal layer HL may have a thickness which is thinner than the thickness of each of the first, second, and third work function electrodes G11, G12, and G13.

The first work function electrode G11, the second work function electrode G12, and the third work function electrode G13 may be formed of materials having different work functions. The first work function electrode G11 may have a higher work function than the second and third work function electrodes G12 and G13. The first work function electrode G11 may include a high work function material. The first work function electrode G11 may have a higher work function than a mid-gap work function of silicon. The second and third work function electrodes G12 and G13 may include a low work function material. The second and third work function electrodes G12 and G13 may have a lower work function than the mid-gap work function of silicon. The high work function material may have a work function which is higher than approximately 4.5 eV, and the low work function material may have a work function which is lower than approximately 4.5 eV. The first work function electrode G11 may include a metal-based material, and the second and third work function electrodes G12 and G13 may include a semiconductor material.

The second and third work function electrodes G12 and G13 may include doped polysilicon which is doped with an N-type dopant (N-type dopant-doped polysilicon). The first work function electrode G11 may include a metal, a metal nitride, or a combination thereof. The first work function electrode G11 may include tungsten, titanium nitride, or a combination thereof. A barrier material may be further formed between the second and third work function electrodes G12 and G13 and the first work function electrode G11.

According to an embodiment of the present invention, each of the upper and lower horizontal lines G1 and G2 of the second conductive line DWL may include the second work function electrode G12—the first work function electrode G11—the third work function electrode G13 that are laterally, e.g., horizontally disposed in the second direction D2. The first work function electrode G11 may include a metal, and the second work function electrode G12 and the third work function electrode G13 may include polysilicon.

Each of the upper and lower horizontal lines G1 and G2 of the second conductive line DWL may have a PMP (poly Si-Metal-Poly Si) structure in which polysilicon, a metal, and polysilicon are laterally, e.g., horizontally disposed in the second direction D2. In the PMP structure, the first work function electrode G11 may be a metal-based material, and the second and third work function electrodes G12 and G13 may be N-type dopant-doped polysilicon, which is polysilicon doped with an N-type dopant. The N-type dopant may include phosphorus or arsenic.

A first barrier layer G12L may be disposed between the first work function electrode G11 and the second work function electrode G12. A second barrier layer G13L may be disposed between the first work function electrode G11 and the third work function electrode G13. The first and second barrier layers G12L and G13L may include titanium nitride, tantalum nitride, tungsten nitride, or molybdenum nitride. The second barrier layer G13L may cover or be on the upper surface, the lower surface, and one side surface of the first work function electrode G11.

The first work function electrode G11 may have a greater volume than the second and third work function electrodes G12 and G13, and thus the second conductive line DWL may have a low resistance. The first work function electrodes G11 of the upper and lower horizontal lines G1 and G2 may vertically overlap in the first direction D1 with the horizontal layer HL interposed therebetween. The second and third work function electrodes G12 and G13 of the upper and lower horizontal lines G1 and G2 may vertically overlap in the first direction D1 with the horizontal layer HL interposed therebetween. The overlapping area between the first work function electrode G11 and the horizontal layer HL may be greater than the overlapping area between the second and third work function electrodes G12 and G13 and the horizontal layer HL. The first work function electrode G11 may extend in the third direction D3, and the second and third work function electrodes G12 and G13 may have an independent structure that overlaps with the horizontal layer HL. For example, the first work function electrode G11 may include a channel overlapping portion WLP and a channel non-overlapping portion NOL, and the second and third work function electrodes G12 and G13 may be a portion of the channel overlapping portion WLP. The second and third work function electrodes G12 and G13 and the first work function electrode G11 may directly contact each other.

As described above, each of the upper and lower horizontal lines G1 and G2 may have a triple electrode structure including the first, second and third work function electrodes G11, G12 and G13. The second conductive line DWL may include a pair of first work function electrodes G11, a pair of second work function electrodes G12, and a pair of third work function electrodes G13 that extend in the third direction D3 crossing the horizontal layer HL with the horizontal layer HL interposed therebetween. The first work function electrodes G11, the second work function electrodes G12, and the third work function electrodes G13 may vertically overlap with the channel CH.

Each of the second conductive lines DWL may include a channel overlapping portion WLP and a channel non-overlapping portion NOL as illustrated in FIG. 1C. The channel overlapping portions WLP may have a cross shape or a rhombus shape. The channel overlapping portions WLP may fully overlap with the channel CH. The second conductive line DWL extending in the third direction D3 by the channel overlapping portions WLP and the channel non-overlapping portions NOL may have notched sidewalls. From the perspective of a top view, the notched sidewalls may be provided by protruding portions by the channel overlapping portions WLP and recessed portions by the channel non-overlapping portions NOL. The channel overlapping portion WLP may include first work function electrodes G11, second work function electrodes G12, and third work function electrodes G13, and the first work function electrodes G11, the second work function electrodes G12 and the third work function electrodes G13 may vertically overlap with the channel CH.

In the second direction D2, the first work function electrode G11 having a high work function may be disposed at the center of the second conductive line DWL, and the second and third work function electrodes G2 and G3 having a low work function may be disposed at both ends of the second conductive line DWL. In this way, it is possible to improve the problem of leakage current, such as Gate Induced Drain Leakage (GIDL).

As the first work function electrode G11 having a high work function is disposed at the center of the second conductive line DWL, the threshold voltage of the switching element TR may be increased. Since the second work function electrode G12 of the second conductive line DWL has a low work function, a low electric field may be formed between the first conductive line BL and the second conductive line DWL. Since the third work function electrode G13 of the second conductive line DWL has a low work function, a low electric field may be formed between the data storage element CAP and the second conductive line DWL.

As described above, the memory cell MC1 may include the second conductive line DWL having a triple work function electrode structure. Each of the upper and lower horizontal lines G1 and G2 of the second conductive line DWL may include a first work function electrode G11, a second work function electrode G12, and a third work function electrode G13. The first work function electrode G11 may overlap with the channel CH, and the second work function electrode G12 may be disposed adjacent to the first conductive line BL and the first doped region SR. The third work function electrode G13 may be disposed adjacent to the data storage element CAP and the second doped region DR. Due to the low work function of the second work function electrode G12, a low electric field may be formed between the second conductive line DWL and the first conductive line BL, thereby reducing leakage current. Due to the low work function of the third work function electrode G13, a low electric field may be formed between the second conductive line DWL and the data storage element CAP, thereby improving leakage current. Due to the high work function of the first work function electrode G11, the threshold voltage of the switching element TR may be increased. Also, the high electric field of the first work function electrode G11 may reduce the height of the memory cell MC1, which is advantageous in terms of integration.

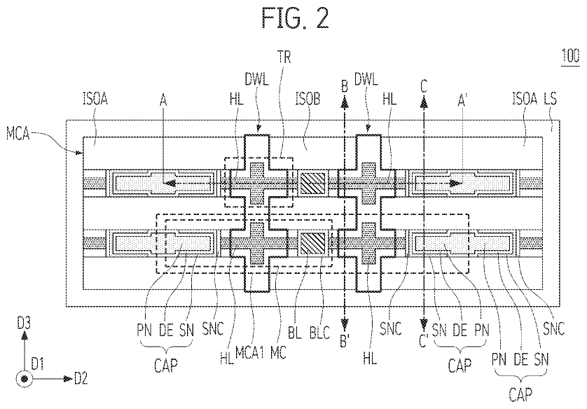

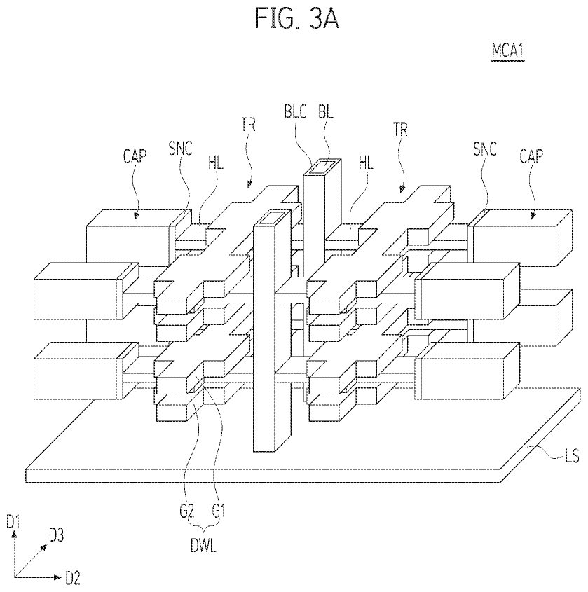

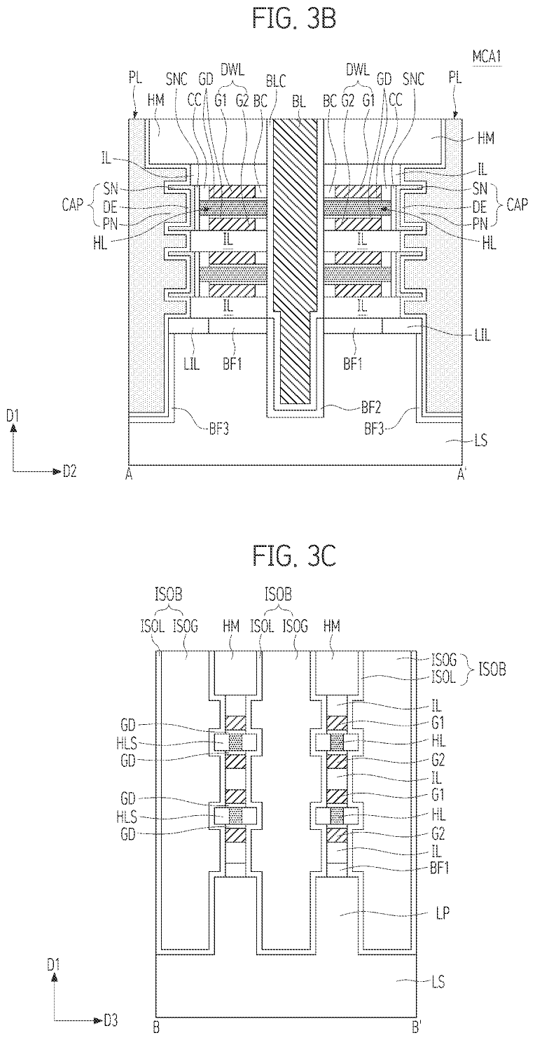

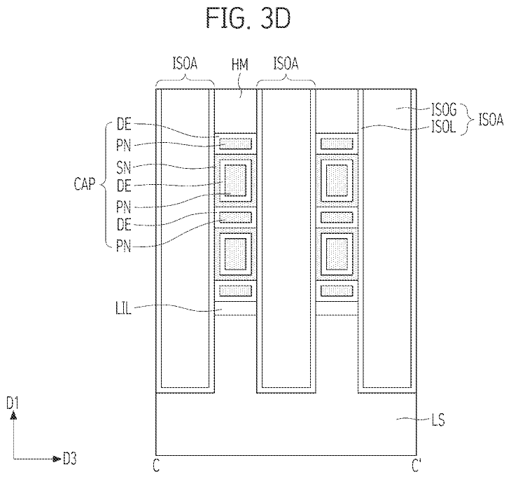

FIG. 2 is a schematic plan view illustrating a semiconductor device in accordance with an embodiment of the present invention. FIG. 3A is a schematic perspective view illustrating a first memory cell array MCA1 shown in FIG. 2. FIG. 3B is a cross-sectional view taken along a line A-A′ shown in FIG. 2. FIG. 3C is a cross-sectional view taken along a line B-B′ shown in FIG. 2. FIG. 3D is a cross-sectional view taken along a line C-C′ shown in FIG. 2.

Referring to FIGS. 2, 3A, 3B, 3C, and 3D, the semiconductor device 100 may include a memory cell array MCA. The memory cell array MCA may include a plurality of memory cells MC. As for the memory cells MC, FIGS. 1A to 1C may be referred to. Each memory cell MC may include a first conductive line BL, a switching element TR, and a data storage element CAP.

The memory cell array MCA may include a three-dimensional array of memory cells MC. The 3D array of memory cells MC may include a column array of memory cells MC and a row array of memory cells MC. The column array of memory cells MC may have a plurality of memory cells MC that are stacked in the first direction D1, and the row array of memory cells MC may have a plurality of memory cells MC that are laterally, e.g., horizontally disposed in the second direction D2 and the third direction D3. The memory cell array MCA may include sub-memory cell arrays MCA1 that are disposed adjacent to each other in the second direction D2. The sub-memory cell array MCA1 may have a mirror-type structure in which two memory cells MC share the first conductive line BL. According to another embodiment of the present invention, the semiconductor device 100 may further include sub-memory cell arrays of a mirror-type structure in which two memory cells MC share the second electrode PN of the data storage element CAP. The memory cell array MCA may include a plurality of sub-memory cell arrays MCA1 in which memory cells MC are vertically stacked in the first direction D1. The memory cell array MCA may include a plurality of sub-memory cell arrays MCA1 that are horizontally arranged in the third direction D3.

According to another embodiment of the present invention, in the memory cell array MCA, a plurality of sub-memory cell arrays MCA1 may be disposed in the second direction D2. For example, in the second direction D2, the data storage element CAP, the switching element TR, the first conductive line BL, and the switching element TR may be alternately disposed in the mentioned order.

Inter-cell dielectric layers IL may be disposed between the memory cells MC that are stacked in the first direction D1. The inter-cell dielectric layers IL may include silicon oxide. The inter-cell dielectric layers IL may be referred to as lateral (e.g., horizontal) inter-cell dielectric layers. A hard mask layer HM may be disposed over the uppermost level inter-cell dielectric layer IL.

Cell isolation layers ISOA and ISOB may be disposed between the neighboring memory cells MC in the third direction D3. The cell isolation layers ISOA and ISOB may be referred to as vertical inter-cell dielectric layers. The cell isolation layers ISOA and ISOB may include silicon oxide, silicon carbon oxide (SiCO), silicon nitride, or a combination thereof. The cell isolation layers ISOA and ISOB may include first cell isolation layers ISOA and second cell isolation layers ISOB. The first cell isolation layers ISOA and the second cell isolation layers ISOB may extend vertically in the first direction D1. The first cell isolation layers ISOA and the second cell isolation layers ISOB may have a pillar structure extending vertically in the first direction D1. The first cell isolation layers ISOA and the second cell isolation layers ISOB may be alternately and repeatedly disposed in the second direction D2. First cell isolation layers ISOA may be disposed between the data storage elements CAP in the third direction D3. Second cell isolation layers ISOB may be disposed between the first conductive lines BL in the third direction D3. A second conductive line DWL may be disposed between the first cell isolation layers ISOA and the second cell isolation layers ISOB in the second direction D2. Each of the first cell isolation layers ISOA and the second cell isolation layers ISOB may include a stack of a cell isolation liner layer ISOL and a cell isolation gap-fill layer ISOG. The cell isolation liner layers ISOL may include silicon carbon oxide, and the cell isolation gap-fill layers ISOG may include silicon carbon oxide.

The memory cell array MCA may be disposed over the lower structure LS.

The memory cell array MCA may include a plurality of second conductive lines DWL that are vertically stacked in the first direction D1. The memory cell array MCA may include a plurality of horizontal layers HL that are vertically stacked in the first direction D1. The memory cell array MCA may include a plurality of data storage elements CAP that are vertically stacked in the first direction D1. The memory cell array MCA may include a plurality of first conductive lines BL that are spaced apart from each other in the third direction D3.

Each of the second conductive lines DWL may include a channel overlapping portion WLP and channel non-overlapping portions NOL as illustrated in FIG. 1C. The channel overlapping portion WLP may have a cross shape or a rhombus shape. The channel overlapping portion WLP may fully overlap with the channel CH. The second conductive line DWL extending in the third direction D3 may include a plurality of channel overlapping portions WLP. As the channel overlapping portions WLP and the channel non-overlapping portions NOL are alternately repeated in the third direction D3, the second conductive line DWL may have a notched sidewall.

A plurality of first passivation layers BF1 may be disposed between the lowermost second conductive line DWL among the second conductive lines DWL and the lower structure LS. A second passivation layer BF2 may be disposed between the first conductive line BL and the lower structure LS. Third passivation layers BF3 may be disposed between the data storage element CAP and the lower structure LS. The first to third passivation layers BF1, BF2, and BF3 may include a dielectric material. The first to third passivation layers BF1, BF2, and BF3 may include silicon oxide. The first to third passivation layers BF1, BF2, and BF3 may electrically disconnect the first conductive line BL, the second conductive lines DWL, and the data storage elements CAP from the lower structure LS. The first to third passivation layers BF1, BF2, and BF3 may be referred to as bottom dielectric layers or bottom passivation layers. The lowermost level inter-cell dielectric layer LIL may be disposed between the first passivation layers BF1 and the data storage element CAP.

The first conductive lines BL may extend vertically from the upper portion of the lower structure LS in the first direction D1. The horizontal layers HL may extend in the second direction D2 crossing the first direction D1. The second conductive lines DWL may extend in the third direction D3 crossing the first and second directions D1 and D2.

From the perspective of a top view, the horizontal layers HL may have a cross shape or a rhombus shape. According to another embodiment of the present invention, the side surfaces of the horizontal layer HL may have a bent shape or a round shape. As illustrated in FIG. 1B, the horizontal layer HL may include a channel CH, a first doped region SR between the channel CH and the first conductive line BL, and a second doped region DR between the channel CH and the data storage element CAP. Referring back to FIG. 3C, horizontal layer level spacers HLS may be formed over the side surfaces of the horizontal layers HL. The horizontal layer level spacer HLS may include a dielectric material such as silicon oxide.

A first capping layer BC may be disposed between the second conductive line DWL and the first conductive line BL. A second capping layer CC may be disposed between the second conductive line DWL and the first electrode SN of the data storage element. The first capping layer BC may be disposed between the upper horizontal line G1 and the first conductive line BL, and the first capping layer BC may be disposed between the lower horizontal line G2 and the first conductive line BL. The second capping layer CC may be disposed between the upper horizontal line G1 and the first electrode SN of the data storage element CAP, and the second capping layer CC may be disposed between the lower horizontal line G2 and the first electrode SN of the data storage element CAP. One memory cell MC may include a pair of first capping layers BC and a pair of second capping layers CC.

The first and second capping layers BC and CC may include a dielectric material. The first and second capping layers BC and CC may include silicon oxide, silicon nitride, silicon carbon oxide, an air gap, or a combination thereof. The first capping layer BC may include silicon oxide, and the second capping layer CC may include a stack of silicon oxide and silicon nitride. According to another embodiment of the present invention, the first capping layer BC may include a stack of silicon oxide and silicon nitride.

The memory cell MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon, and each of the first doped region SR and the second doped region DR may include impurities diffused from the first and second contact nodes BLC and SNC.

The horizontal layers HL of the switching elements TR disposed laterally, e.g., horizontally in the third direction D3 may share one second conductive line DWL. The horizontal layers HL of the switching elements TR disposed laterally, e.g., horizontally in the third direction D3 may be coupled to different first conductive lines BL. The switching elements TR stacked in the first direction D1 may share one first conductive line BL. The switching elements TR disposed laterally, e.g., horizontally in the third direction D3 may share one second conductive line DWL.

The first cell isolation layers ISOA may be disposed between the first electrodes SN of the data storage elements CAP in the third direction D3. The first electrodes SN may be isolated from each other by the first cell isolation layers ISOA. The second electrodes PN of the data storage elements CAP may be coupled to a common plate PL.

The lower structure LS may include a semiconductor substrate, a metal interconnection structure, a dielectric structure, a conductive structure, a bonding pad structure, and other memory or peripheral circuit units.

For example, the lower structure LS may include a structure in which a peripheral circuit unit, a metal interconnection structure, and a bonding pad structure are sequentially stacked. The memory cell array MCA and the peripheral circuit unit of the lower structure LS may be coupled by wafer bonding.

The peripheral circuit unit of the lower structure LS may be disposed at a lower level than the memory cell array MCA. This may be referred to as a Cell-Over-Peripheral (COP) structure. The peripheral circuit unit may include at least one control circuit for driving the memory cell array MCA. The at least one control circuit of the peripheral circuit unit may include an N-channel transistor, a P-channel transistor, a CMOS circuit, or a combination thereof. The at least one control circuit of the peripheral circuit unit may include an address decoder circuit, a read circuit, a write circuit, and the like. The at least one control circuit of the peripheral circuit unit may include a planar channel transistor, a recess channel transistor, a buried gate transistor, a fin channel transistor (FinFET), and the like.

For example, the peripheral circuit unit may include sub-word line drivers and a sense amplifier. The second conductive lines DWL may be coupled to the sub-word line drivers. The first conductive line BL may be coupled to the sense amplifier.

According to another embodiment of the present invention, the peripheral circuit unit may be disposed at a higher level than the memory cell array MCA. This may be referred to as a Peripheral-Over-Cell (POC) structure. In this case, the lower structure LS may include the first semiconductor substrate, and the peripheral circuit unit may include a second semiconductor substrate.

According to another embodiment of the present invention, the memory cell array MCA may include a Dynamic Random Access Memory (DRAM), an embedded DRAM, a NAND memory, a ferroelectric RAM (FeRAM), a Spin-Transfer Torque RAM (STTRAM), a Phase-Change RAM (PCRAM), or a Resistive RAM (ReRAM).

According to another embodiment of the present invention, the individual memory cell MC may be replaced with the memory cell MC1 shown in FIG. 1D.

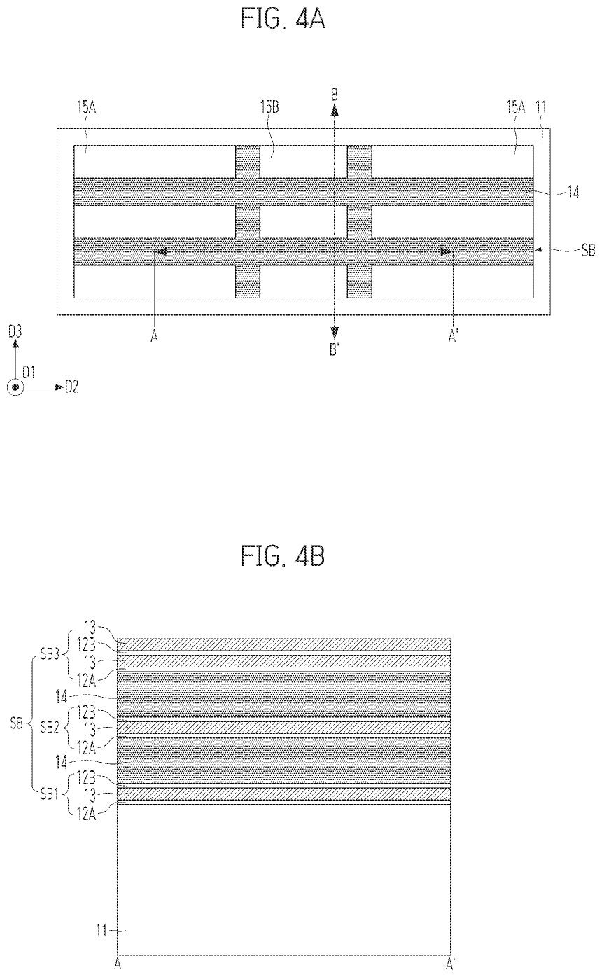

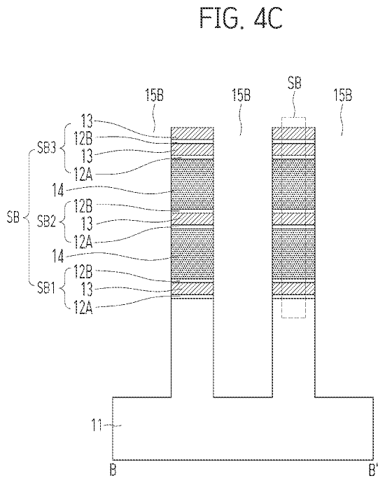

FIGS. 4A to 26B illustrate an example of a method for fabricating a semiconductor device in accordance with embodiments of the present invention.

FIG. 4A is a plan view of the fourth layer 14 level for describing a method for forming a stack body SB and the sacrificial isolation openings 15A and 15B, and FIG. FIG. 4B is a cross-sectional view taken along a line A-A′ shown in FIG. 4A. FIG. 4C is a cross-sectional view taken along a line B-B′ shown in FIG. 4A.

Referring to FIGS. 4A to 4C, a stack body SB may be formed over the lower structure 11. The lower structure 11 may be a material suitable for semiconductor processing. The lower structure 11 may include a conductive material, a dielectric material, a semiconductor material or any combination thereof. Diverse materials may be formed over the lower structure 11. The lower structure 11 may include a semiconductor substrate. The lower structure 11 may be formed of a material containing silicon. The lower structure 11 may include silicon, monocrystalline silicon, polysilicon, amorphous silicon, silicon germanium, monocrystalline silicon germanium, polycrystalline silicon germanium, carbon-doped silicon, combinations thereof, or multi-layers thereof. The lower structure 11 may also include other semiconductor materials, such as germanium. The lower structure 11 may include a III/V-group semiconductor substrate, for example, a compound semiconductor substrate, such as GaAs. The lower structure 11 may include a Silicon-On-Insulator (SOI) substrate.

In the stack body SB, a plurality of sub-stacks may be alternately stacked. Each of the sub-stacks may include a first layer 12A, a second layer 13, a third layer 12B and a fourth layer 14 that are stacked in the mentioned order. The first layers 12A and the third layers 12B may be formed of the same material and may include silicon germanium or monocrystalline silicon germanium. The second layers 13 and the fourth layers 14 may be formed of the same material, and the second layers 13 and the fourth layers 14 may include monocrystalline silicon. The first layers 12A, the second layers 13, the third layers 12B, and the fourth layers 14 may be formed by an epitaxial growth process. The first layer 12A of the lowest level may serve as a seed layer during the epitaxial growth process. The first layers 12A may be thinner than the second layers 13, and the fourth layers 14 may be thicker than the second layers 13.

According to an embodiment of the present invention, the stack body SB may include a plurality of fourth layers 14, a first stack SB1, a second stack SB2, and a third stack SB3. The stack body SB may include a first stack SB1, a fourth layer 14, a second stack SB2, a fourth layer 14, and a third stack SB3 that are stacked in the mentioned order. Each of the first stack SB1, the second stack SB2, and the third stack SB3 may include a three-layer stack of the first layer 12A/second layer 13/third layer 12B. For example, when the first layers 12A and the third layers 12B include a silicon germanium layer and the second layers 13 include a monocrystalline silicon layer, the first stack SB1 and the second stack SB2 and the third stack SB3 may include a stack of first silicon germanium/monocrystalline silicon/second silicon germanium (SiGe/Si/SiGe). The third stack SB3 may further include a second layer 13 over the three-layer stack of the first layer 12A/second layer 13/third layer 12B.

The second layers 13 may include a first monocrystalline silicon layer, and the fourth layers 14 may include a second monocrystalline silicon layer. The second monocrystalline silicon layers may be thicker than the first monocrystalline silicon layers. Accordingly, in the stack body SB, the first stack SB1 may be disposed below the second monocrystalline silicon layers, and the second stack SB2 may be disposed over the second monocrystalline silicon layers. Each of the first and second stacks SB1 and SB2 may include a three-layer stack of a first silicon germanium layer/first monocrystalline silicon layer/second silicon germanium layer, and the second monocrystalline silicon layers may be thicker than the first monocrystalline silicon layers.

The first layers 12A, the second layers 13, and the third layers 12B may be referred to as ‘sacrificial layers’, and the fourth layers 14 may be referred to as recess target layers.

The stack body SB may be referred to as a vertical stack. The stack body SB may be formed by alternating a plurality of sacrificial layers and the recess target layers. The sacrificial layers may include a first stack SB1, a second stack SB2, and a third stack SB3, and each of the first stack SB1, the second stack SB2, and the third stack SB3 may include a three-layer stack of the first layer 12A/second layer 13/third layer 12B. The recess target layers may include fourth layers 14. Each of the sacrificial layers may include a three-layer stack of a first silicon germanium layer/a first monocrystalline silicon layer/a second silicon germanium layer, and each of the recess target layers may include a single layer of a second monocrystalline silicon layer. The second monocrystalline silicon layers may be thicker than the first monocrystalline silicon layers.

As described above with reference to FIGS. 2 to 3D, when the memory cells MC are vertically stacked, the first stack SB1, the fourth layer 14, the second stack SB2, the fourth layer 14 and the third stack SB3 may be alternately stacked several times.

Subsequently, portions of the stack body SB may be etched to form a plurality of sacrificial isolation openings 15A and 15B. The sacrificial isolation openings 15A and 15B may be initial openings for cell isolation, and the sacrificial isolation openings 15A and 15B may include large openings 15A and small openings 15B. The size of the large openings 15A may be greater than the size of the small openings 15B. From the perspective of a top view, the large openings 15A and the small openings 15B may have a rectangular shape. According to another embodiment of the present invention, the large openings 15A and the small openings 15B may have a circular shape or an elliptical shape. According to another embodiment of the present invention, the sacrificial isolation openings 15A and 15B may be referred to as sacrificial isolation trenches. The large openings 15A and the small openings 15B may vertically extend in the first direction D1. The large openings 15A and the small openings 15B may be alternately disposed in the second direction D2. A plurality of large openings 15A may be disposed in the third direction D3. A plurality of small openings 15B may be disposed in the third direction D3. The large openings 15A and the small openings 15B may pass through the stack body SB in the first direction D1.

After the sacrificial isolation openings 15A and 15B are formed, portions of the lower structure 11 exposed below the sacrificial isolation openings 15A and 15B may be etched. As a result, the bottom surfaces of the sacrificial isolation openings 15A and 15B may extend into the lower structure 11. The bottom surfaces of the sacrificial isolation openings 15A and 15B may include a U-shaped profile. Due to the sacrificial isolation openings 15A and 15B, the fourth layers 14 may have a mesh-shaped pattern.

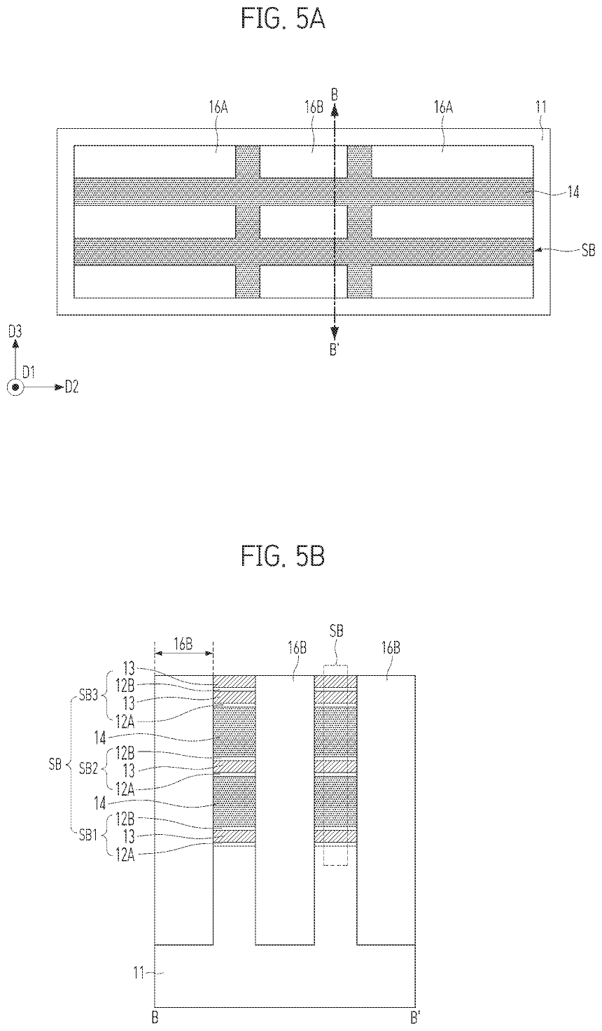

FIG. 5A is a plan view of the fourth layer 14 level illustrating a method for forming the sacrificial isolation layers 16A and 16B, and FIG. 5B is a cross-sectional view taken along a line B-B′ shown in FIG. 5A.

Referring to FIGS. 5A and 5B, sacrificial isolation layers 16A and 16B filling the sacrificial isolation openings 15A and 15B may be formed. The sacrificial isolation layers 16A and 16B may include first sacrificial isolation layers 16A and second sacrificial isolation layers 16B. The first sacrificial isolation layers 16A may fill the large openings 15A, and the second sacrificial isolation layers 16B may fill the small openings 15B.

The first sacrificial isolation layers 16A and the second sacrificial isolation layers 16B may include the same material. The first sacrificial isolation layers 16A and the second sacrificial isolation layers 16B may be formed of a dielectric material. Forming the first sacrificial isolation layers 16A and the second sacrificial isolation layers 16B may include forming sacrificial isolation materials over the stack body SB to fill the sacrificial isolation openings 15A and 15B, and planarizing the sacrificial isolation materials to expose the uppermost layer of the stack body SB. The first sacrificial isolation layers 16A and the second sacrificial isolation layers 16B may have different sizes or different volumes. For example, the size (or volume) of the first sacrificial isolation layers 16A may be greater than that of the second sacrificial isolation layers 16B. The first sacrificial isolation layers 16A and the second sacrificial isolation layers 16B may have the same length in the third direction D3 and different lengths in the second direction D2. The lengths of the first sacrificial isolation layers 16A in the second direction D2 may be greater than the lengths of the second sacrificial isolation layers 16B.

The first sacrificial isolation layers 16A and the second sacrificial isolation layers 16B may extend vertically in the first direction D1. The first sacrificial isolation layers 16A and the second sacrificial isolation layers 16B may be alternately disposed in the second direction D2. A plurality of first sacrificial isolation layers 16A may be disposed in the third direction D3. A plurality of second sacrificial isolation layers 16B may be disposed in the third direction D3. The first sacrificial isolation layers 16A and the second sacrificial isolation layers 16B may pass through the stack body SB in the first direction D1.

The first sacrificial isolation layers 16A and the second sacrificial isolation layers 16B may include the same material. The first sacrificial isolation layers 16A and the second sacrificial isolation layers 16B may be formed of a dielectric material. For example, the first sacrificial isolation layers 16A and the second sacrificial isolation layers 16B may include silicon oxide, silicon nitride, silicon carbon oxide, silicon carbon nitride, or a combination thereof.

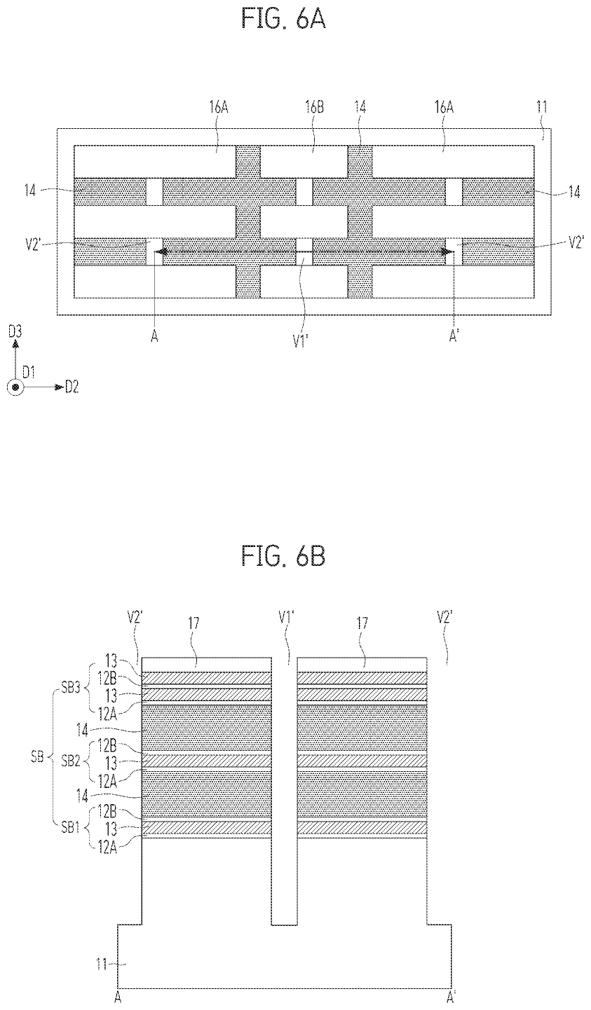

FIG. 6A is a plan view of the fourth layer 14 level illustrating a method for forming sacrificial vertical openings V1′ and V2′, and FIG. 6B is a cross-sectional view taken along a line A-A′ shown in FIG. 6A.

Referring to FIGS. 6A and 6B, a hard mask layer pattern 17 may be formed over the stack body SB, the first sacrificial isolation layers 16A, and the second sacrificial isolation layers 16B. The hard mask layer pattern 17 may include silicon nitride. The hard mask layer pattern 17 may be formed by an etching process using a mask layer. A plurality of hole-type openings may be defined in the hard mask layer pattern 17.

Subsequently, portions of the stack body SB may be etched by using the hard mask layer pattern 17 as an etch barrier. As a result, a plurality of sacrificial vertical openings V1′ and V2′ may be formed in the stack body SB. The sacrificial vertical openings V1′ and V2′ may include first sacrificial vertical openings V1′ and second sacrificial vertical openings V2′. The first sacrificial vertical openings V1′ and the second sacrificial vertical openings V2′ may be hole-type openings. The first sacrificial vertical openings V1′ and the second sacrificial vertical openings V2′ may vertically extend in the first direction D1. The first sacrificial vertical openings V1′ and the second sacrificial vertical openings V2′ may be formed by etching the stack body SB between the first and second sacrificial isolation layers 16A and 16B. The first sacrificial vertical openings V1′ may be formed by etching the stack body SB between the second sacrificial isolation layers 16B. The second sacrificial vertical openings V2′ may be formed by etching the stack body SB between the first sacrificial isolation layers 16A. The first sacrificial vertical openings V1′ may be disposed between the second sacrificial isolation layers 16B in the third direction D3. The second sacrificial vertical openings V2′ may be disposed between the first sacrificial isolation layers 16A in the third direction D3. From the perspective of a top view, cross sections of the first and second sacrificial vertical openings V1′ and V2′ may be rectangular, circular or elliptical.

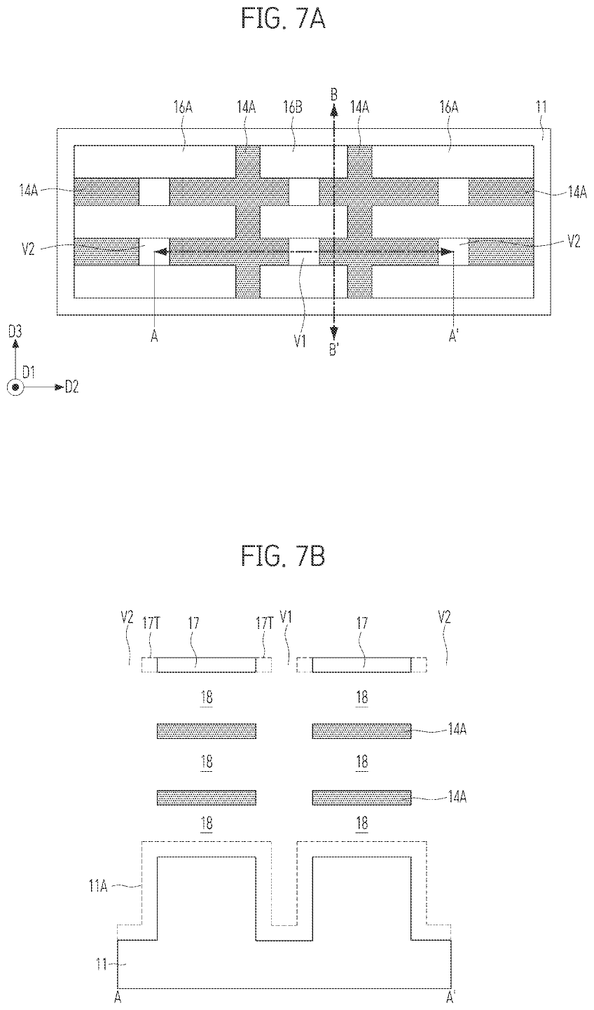

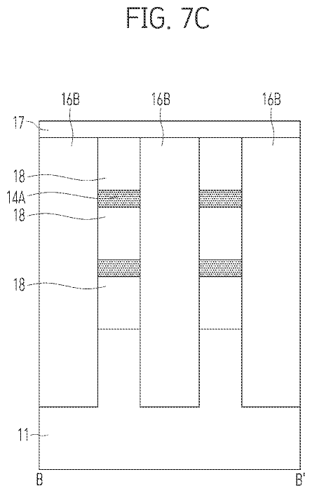

FIG. 7A is a plan view illustrating a method for forming a preliminary horizontal layer 14A, FIG. 7B is a cross-sectional view taken along a line A-A′ shown in FIG. 7A, and FIG. 7C is a cross-sectional view taken along a line B-B′ shown in FIG. 7A.

Referring to FIGS. 7A to 7C, a portion of the hard mask layer pattern 17 may be trimmed (refer to a reference numeral ‘17T’).

Subsequently, the first and third layers 12A and 12B may be selectively removed through the first and second sacrificial vertical openings V1′ and V2′. In order to selectively remove the first layers 12A and the third layers 12B, a difference between the etch selectivities of the second and fourth layers 13 and 14 and the etch selectivities of the first and third layers 12A and 12B may be used. The first layers 12A and the third layers 12B may be removed by a wet etching process or a dry etching process. For example, when the first layers 12A and the third layers 12B include a silicon germanium layer and the second layers 13 and the fourth layers 14 include a monocrystalline silicon layer, the silicon germanium layers may be etched using an etchant or an etch gas having a selectivity with respect to the monocrystalline silicon layers.

Subsequently, the second layers 13 and the fourth layers 14 may be recessed. In order to recess the second layers 13 and the fourth layers 14, a wet etching process or a dry etching process may be used. According to this embodiment of the present invention, the fourth layers 14 may be partially etched while the second layers 13 are removed. As a result, the second layers 13 may be removed, and the fourth layers 14 may become thin as indicated by a reference numeral ‘14A’. A recess process for forming the thin fourth layer 14A, that is, the preliminary horizontal layers 14A, may be referred to as a thinning process or a trimming process of the fourth layers 14. To form the preliminary horizontal layers 14A, the upper surfaces, lower surfaces and side surfaces of the fourth layers 14 may be recessed. The preliminary horizontal layers 14A may be referred to as thin-body active layers. The preliminary horizontal layers 14A may extend in a lateral direction. In some embodiments, the lateral direction may be a horizontal direction but the present invention is not limited thereto. The preliminary horizontal layers 14A may include a monocrystalline silicon layer. A recess process for forming the preliminary horizontal layers 14A may use, for example, Hot SC-1 (HSC1). HSC1 may include a solution in which ammonium hydroxide (NH₄OH), hydrogen peroxide (H₂O₂) and water (H₂O) are mixed at a ratio of approximately 1:4:20. The second layers 13 and the fourth layers 14 may be selectively etched using the HSC1.

As described above, the preliminary horizontal layers 14A may be formed by the recess process for the fourth layers 14, and horizontal recesses 18 (e.g., horizontal recesses) may be formed between the preliminary horizontal layers 14A. The preliminary horizontal recesses 18 may extend laterally, e.g., horizontally. Each of the upper and lower surfaces of the preliminary horizontal layers 14A may include a flat surface.

From the perspective of a top view, the preliminary horizontal layers 14A may have a cross shape. The side surfaces of the preliminary horizontal layers 14A may have a bent shape or a rounded shape.

After the preliminary horizontal layers 14A are formed, the first and second sacrificial vertical openings may be expanded as indicated by reference symbols ‘V1’ and ‘V2’. The preliminary horizontal layers 14A may be spaced apart from each other by the first and second sacrificial vertical openings V1 and V2 in the second direction D2. The preliminary horizontal layers 14A may have a shape in which a plurality of cross shapes are merged in the third direction D3.

While the preliminary horizontal layers 14A are formed, the surface of the lower structure 11 may be recessed to a predetermined depth (refer to a reference numeral ‘11A’). As a result, the depths of the first and second sacrificial vertical openings V1′ and V2′ may increase.

First sacrificial vertical openings V1 and second sacrificial vertical openings V2 may be alternately disposed between the preliminary horizontal layers 14A in the second direction D2. The first sacrificial vertical openings V1 may be disposed between the second sacrificial isolation layers 16B in the third direction D3, and the second sacrificial vertical openings V2 may be disposed between the first sacrificial isolation layers 16A in the third direction D3.

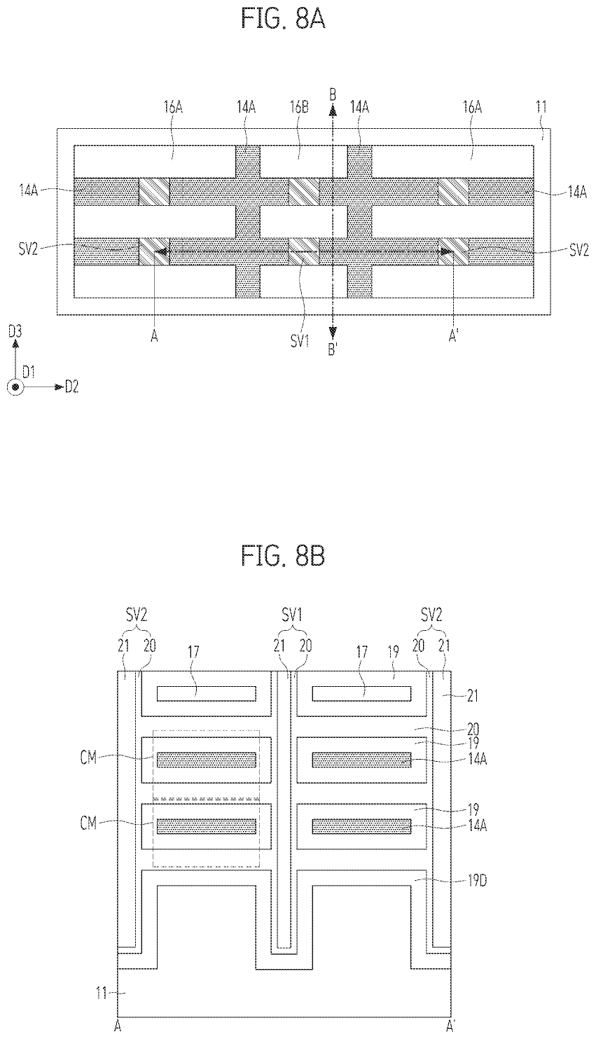

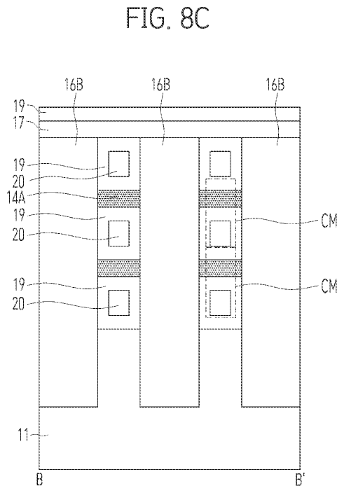

FIG. 8A is a plan view illustrating a method for forming the first dielectric layer 19 and the second dielectric layer 20, and FIG. 8B is a cross-sectional view taken along a line A-A′ shown in FIG. 8A. FIG. 8C is a cross-sectional view taken along a line B-B′ shown in FIG. 8A.

Referring to FIGS. 8A to 8C, first dielectric layers 19 covering the preliminary horizontal layers 14A may be formed. The first dielectric layers 19 may include silicon nitride. The first dielectric layers 19 may fully cover the upper, lower and side surfaces of the preliminary horizontal layers 14A.

While the first dielectric layers 19 are formed, a dummy dielectric layer 19D may be formed over the surface of the lower structure 11. Some of the first dielectric layers 19 may fully cover the upper, lower and side surfaces of the hard mask layer pattern 17.

Subsequently, a second dielectric layer 20 may be formed over the first dielectric layers 19. The second dielectric layer 20 may fill between first dielectric layers 19 that are disposed vertically adjacent to each other. The second dielectric layer 20 may include silicon oxide. Portions of the second dielectric layer 20 may be conformally formed over the surfaces of the first and second sacrificial vertical openings V1 and V2. The horizontal recesses 18 in FIGS. 7B and 7C) may be filled by the first dielectric layer 19 and the second dielectric layer 20.

Subsequently, sacrificial pillars 21 may be formed over the second dielectric layer 20 that is disposed in the first and second sacrificial vertical openings V1 and V2. The sacrificial pillars 21 may be of a sacrificial material and may include amorphous carbon. According to another embodiment of the present invention, a pillar capping layer may be further formed over the sacrificial pillars 21. The pillar capping layer may include a metal-based material. The pillar capping layer may include titanium nitride. Forming the sacrificial pillars 21 may include depositing a sacrificial material and planarizing the sacrificial material. The planarization process for forming the sacrificial pillars 21 may be performed until the first dielectric layer 19 at the uppermost level is exposed. Subsequently, the uppermost-level second dielectric layers 20 may also be planarized until the uppermost-level first dielectric layer 19 is exposed. The sacrificial pillars 21 may not be formed between the vertically stacked first dielectric layers 19.

The second dielectric layer 20 and the sacrificial pillars 21 may form first and second sacrificial pillar structures SV1 and SV2 that fill the first and second sacrificial vertical openings V1 and V2. The first sacrificial pillar structure SV1 may fill the first sacrificial vertical openings V1, and the second sacrificial pillar structure SV2 may fill the second sacrificial vertical openings V2. According to another embodiment of the present invention, the first and second sacrificial pillar structures SV1 and SV2 may include a dielectric material, a carbon-containing material, a metal-based material, or a combination thereof. According to another embodiment of the present invention, the first and second sacrificial pillar structures SV1 and SV2 may include silicon oxide, silicon nitride, titanium nitride, amorphous carbon, or a combination thereof. From the perspective of a top view, the first sacrificial pillar structure SV1 and the second sacrificial pillar structure SV2 may have a rectangular cross-section. The first sacrificial pillar structure SV1 and the second sacrificial pillar structure SV2 may be hole-type sacrificial pillars. According to another embodiment of the present invention, portions of the first dielectric layer 19 may be conformally formed over the surfaces of the first and second sacrificial vertical openings V1 and V2, and thus the first and second sacrificial pillar structures SV1 and SV2 may further include portions of the first dielectric layer 19.

Referring back to FIG. 8C, the first dielectric layers 19 may be formed between the preliminary horizontal layers 14A, and second dielectric layers 20 may be disposed in the inside of the first dielectric layers 19. The first dielectric layers 19 may surround the second dielectric layers 20. The first dielectric layers 19 may include a first surrounding portion and a second surrounding portion. The first surrounding portion may surround the preliminary horizontal layers 14A in an A-A′ direction, and the second surrounding portion may surround the second dielectric layers 20 in a B-B′ direction.

As described above, a cell mold structure may be formed by forming the preliminary horizontal layers 14A, the first dielectric layers 19, and the second dielectric layers 20. The cell mold structure may include a plurality of cell molds CM. Each cell mold CM may include a plurality of mold layers. The mold layers may refer to the preliminary horizontal layers 14A, the first dielectric layers 19 and the second dielectric layers 20. Each cell mold CM may include an Oxide-Nitride-Silicon-Nitride (ONSN) stack. Here, the ONSN stack may refer to a structure in which silicon oxide, a first silicon nitride, a monocrystalline silicon layer, and a second silicon nitride are sequentially stacked. Silicon oxide may correspond to the second dielectric layers 20, and the first and second silicon nitrides may correspond to the first dielectric layers 19. The monocrystalline silicon layer may correspond to the preliminary horizontal layers 14A. A cell mold structure including a plurality of cell molds CM may be referred to as a vertical stack. In another aspect, the cell mold structure may include an Oxide-Nitride-Silicon-Nitride-Oxide (ONSNO) stack. Here, the ONSNO stack may refer to a structure in which a first silicon oxide, a first silicon nitride, a monocrystalline silicon layer, a second silicon nitride, and a second silicon oxide are sequentially stacked.

As described above, the sub-stacks of the stack body SB may be replaced with the cell molds CM through a series of the processes according to FIGS. 4A to 8C. The first layers 12A, the second layers 13 and the third layers 12B may be replaced with the first dielectric layers 19 and the second dielectric layers 20. The fourth layers 14 may become the preliminary horizontal layers 14A by a recess process. The first dielectric layers 19 may be referred to as a trimming target layer.

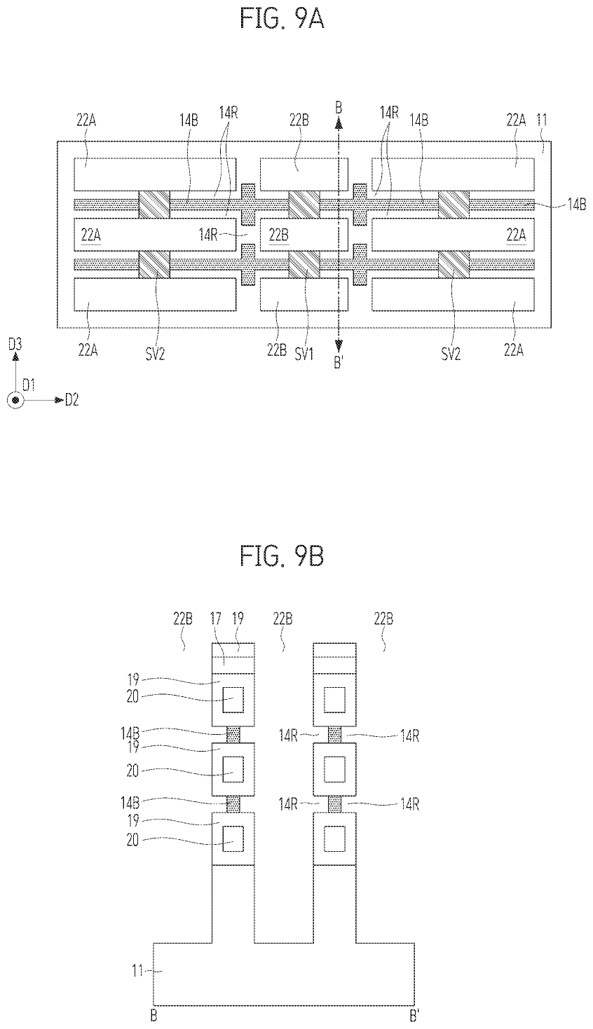

FIG. 9A is a plan view illustrating a method for forming cell isolation openings 22A and 22B and horizontal layers 14B, and FIG. 9B is a cross-sectional view taken along a line B-B′ shown in FIG. 9A.

Referring to FIGS. 9A and 9B, to form the cell isolation openings 22A and 22B, the first and second sacrificial isolation layers 16A and 16B may be removed. While the first and second sacrificial isolation layers 16A and 16B are removed, the first and second sacrificial pillar structures SV1 and SV2 may be covered by a mask layer. The side surfaces of the preliminary horizontal layers 14A and the first dielectric layers 19 may be exposed in the B-B′ direction by the cell isolation openings 22A and 22B.

Subsequently, the side surfaces of the preliminary horizontal layers 14A may be trimmed in the second and third directions D2 and D3 through the cell isolation openings 22A and 22B. As a result, trimmed horizontal layers 14B may be formed. Horizontal layer level gaps 14R may be formed over the side surfaces of the horizontal layers 14B. The horizontal layer level gaps 14R and the horizontal layers 14B may be disposed between the first dielectric layers 19. The horizontal layers 14B may be referred to as ‘trimmed horizontal layer patterns’. In some embodiments, the horizontal layers 14B may be horizontal layers and may be referred to as ‘trimmed horizontal layer patterns’.

While the horizontal layers 14B are formed, the surface of the lower structure 11, for example, the bottom surface of the cell isolation openings 22A and 22B may be expanded.

The horizontal layers 14B may be disposed between the first sacrificial pillar structure SV1 and the second sacrificial pillar structure SV2 in the second direction D2. From the perspective of a top view, the horizontal layers 14B may have a cross shape. The horizontal layers 14B may have a cross shape which is smaller in size than the preliminary horizontal layers 14A. The preliminary horizontal layers 14A may have a shape in which a plurality of cross shapes are merged, and the horizontal layers 14B may have a shape in which the cross shapes are individually separated in the third direction D3. The horizontal layer level gaps 14R may be formed between the horizontal layers 14B that are disposed in the third direction D3. First and second sacrificial pillar structures SV1 and SV2 may be disposed between the horizontal layers 14B in the second direction D2.

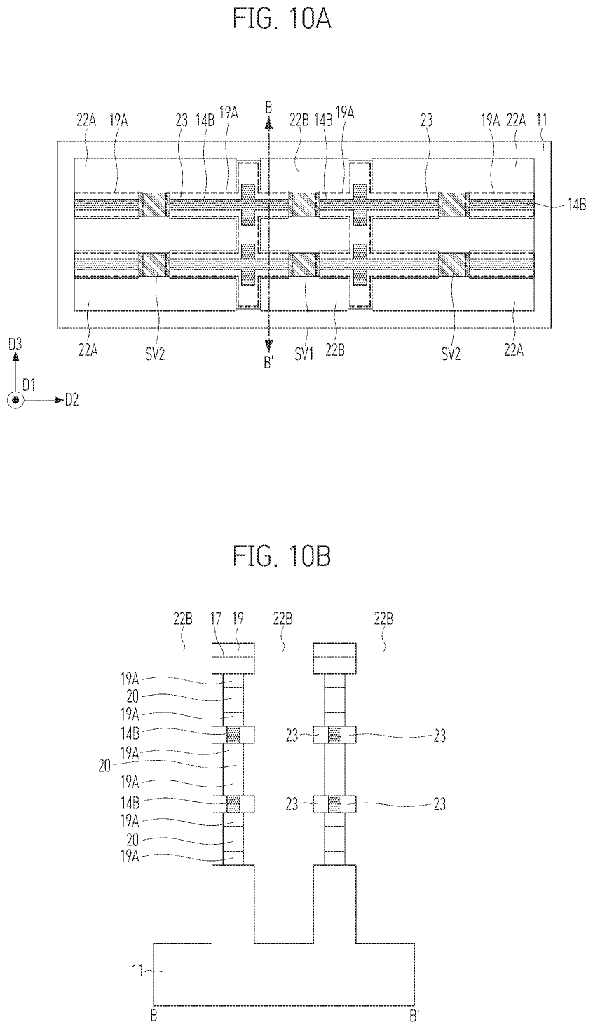

FIG. 10A is a plan view illustrating a method for forming horizontal layer level spacers 23 and the first dielectric layers 19A, and FIG. 10B is a cross-sectional view taken along a line B-B′ shown in FIG. 10A.

Referring to FIGS. 10A and 10B, the horizontal layer level spacers 23 may be formed over the side surfaces of the horizontal layers 14B. Forming the horizontal layer level spacers 23 may include forming a spacer material on the side surfaces of the horizontal layers 14B and etching the spacer material. The horizontal layer level spacers 23 may include a dielectric material, for example, silicon oxide. The horizontal layer level spacers 23 may fill the horizontal layer level gaps 14R. The horizontal layers 14B disposed in the third direction D3 may be separated from each other by the horizontal layer level spacers 23.

Subsequently, portions of the first dielectric layers 19 may be laterally trimmed (e.g., horizontally trimmed) through the cell isolation openings 22A and 22B. After the trimming process, the first dielectric layers 19 may remain as indicated by a reference numeral 19A. Accordingly, from the perspective of B-B′, a pair of the first dielectric layers 19A may be disposed between the horizontal layers 14B, and one second dielectric layer 20 may be disposed between the first dielectric layers 19A of a pair.

Referring to FIGS. 9A to 10B, the width of the first dielectric layers 19A in the third direction D3 between the cell isolation openings 22A and 22B may be greater than the width of the horizontal layers 14B. That is, the trimming depth of the first dielectric layers 19 in the third direction D3 may be smaller than the trimming depth of the preliminary horizontal layers 14A.

A pair of the first dielectric layers 19A may vertically overlap with one horizontal layer 14B. The trimmed first dielectric layers 19A may be referred to as trimmed first dielectric layers.

As described above, the first dielectric layers 19 and the preliminary horizontal layers 14A may be trimmed horizontally by a series of the processes according to FIGS. 9A to 10B. As a result, the cell molds may include the horizontal layers 14B, the first dielectric layers 19A, and the second dielectric layers 20.

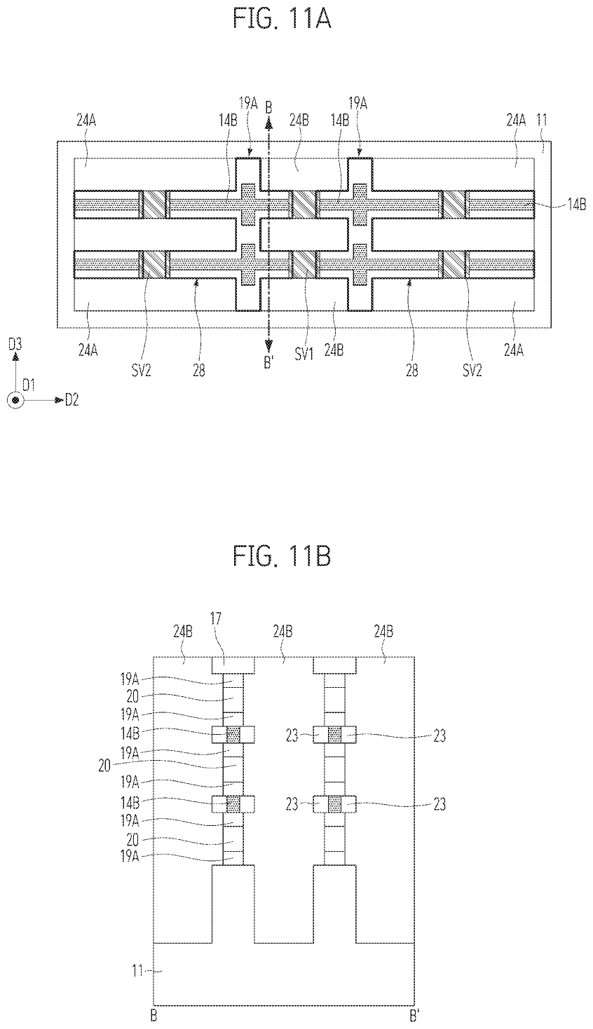

FIG. 11A is a plan view illustrating a method for forming the cell isolation layers 24A and 24B, and FIG. 11B is a cross-sectional view taken along a line B-B′ shown in FIG. 11A. FIG. 11A may be a plan view of the first dielectric layer 19A level illustrating a method for forming the cell isolation layers 24A and 24B.

Referring to FIGS. 11A and 11B, the cell isolation layers 24A and 24B filling the cell isolation openings 22A and 22B may be formed. The cell isolation layers 24A and 24B may include first cell isolation layers 24A and second cell isolation layers 24B. The first cell isolation layers 24A and the second cell isolation layers 24B may include the same material. The first cell isolation layers 24A and the second cell isolation layers 24B may be formed of a dielectric material. For example, the first cell isolation layers 24A and the second cell isolation layers 24B may include silicon oxide, silicon nitride, silicon carbon oxide, silicon carbon nitride, or a combination thereof. From the perspective of a top view, the outermost materials of the first cell isolation layers 24A and the second cell isolation layers 24B may include silicon oxide.

Forming the first cell isolation layers 24A and the second cell isolation layers 24B may include forming a cell isolation material that fills the cell isolation openings 22A and 22B and planarizing the cell isolation material and the uppermost first dielectric layer 19A to expose the surface of the hard mask layer pattern 17. The first cell isolation layers 24A and the second cell isolation layers 24B may have different sizes or different volumes. The first cell isolation layers 24A and the second cell isolation layers 24B may include a double structure of silicon oxide and silicon carbon oxide. For example, silicon carbon oxide may be deposited after silicon oxide is deposited. According to another embodiment of the present invention, the first and second cell isolation layers 24A and 24B may include an embedded air gap, and the embedded air gap may be provided when silicon carbon oxide is deposited. A second sacrificial pillar structure SV2 may be disposed between the first cell isolation layers 24A in the third direction D3, and a first sacrificial pillar structure SV1 may be disposed between the second cell isolation layers 24B in the third direction D3. The first and second cell isolation layers 24A and 24B may extend vertically in the first direction D1.

The first and second cell isolation layers 24A and 24B may correspond to the cell isolation layers ISOA and ISOB as illustrated in FIGS. 2 to 3D. Each of the first and second cell isolation layers 24A and 24B may include a stack of a cell isolation liner layer ISOL and a cell isolation gap-fill layer ISOG, as illustrated in FIGS. 3C and 3D. The cell isolation liner layers ISOL may include silicon oxide, and the cell isolation gap-fill layers ISOG may include silicon carbon oxide. According to another embodiment of the present invention, the first and second cell isolation layers 24A and 24B may include an embedded air gap, and the embedded air gap may be provided when the cell isolation gap-fill layers ISOG are formed.

The first and second cell isolation layers 24A and 24B may directly contact the first dielectric layers 19A. The horizontal layer level spacers 23 may be disposed between the horizontal layers 14B and the first and second cell isolation layers 24A and 24B.

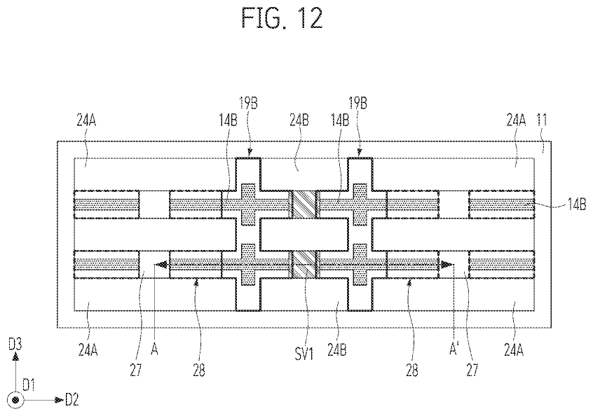

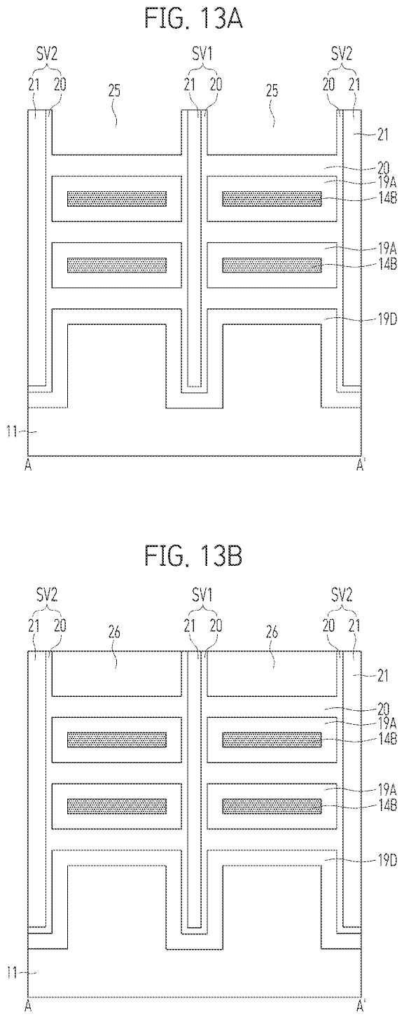

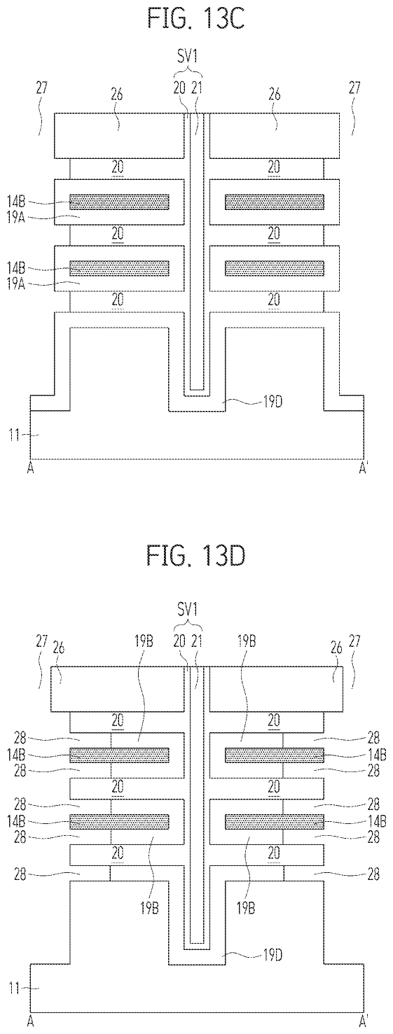

FIG. 12 is a plan view illustrating a method for forming the first dielectric layer patterns 19B, and FIGS. 13A to 13D are cross-sectional views illustrating a method for forming the first dielectric layer patterns 19B according to the line A-A′ shown in FIG. 12.

First, referring to FIG. 13A, the hard mask layer 17 and the uppermost-level first dielectric layer 19A may be removed to form hard mask layer level recesses 25.

Referring to FIG. 13B, a top dielectric layer 26 filling the hard mask layer level recesses 25 may be formed. The top dielectric layer 26 may include silicon oxide.

Referring to FIG. 13C, initial vertical openings 27 may be formed by removing the second sacrificial pillar structures SV2. Subsequently, the second dielectric layers 20 may be laterally recessed, e.g., horizontally recessed, and thus, the first dielectric layers 19A and the dummy dielectric layer 19D may be exposed by the initial vertical openings 27.

Referring to FIG. 13D, the dummy dielectric layer 19D and the first dielectric layers 19A may be selectively laterally recessed (e.g., horizontally recessed). As a result, the first dielectric layer patterns 19B and the dielectric layer level recesses 28 may be formed. Portions of the horizontal layers 14B may be exposed by the dielectric layer level recesses 28.

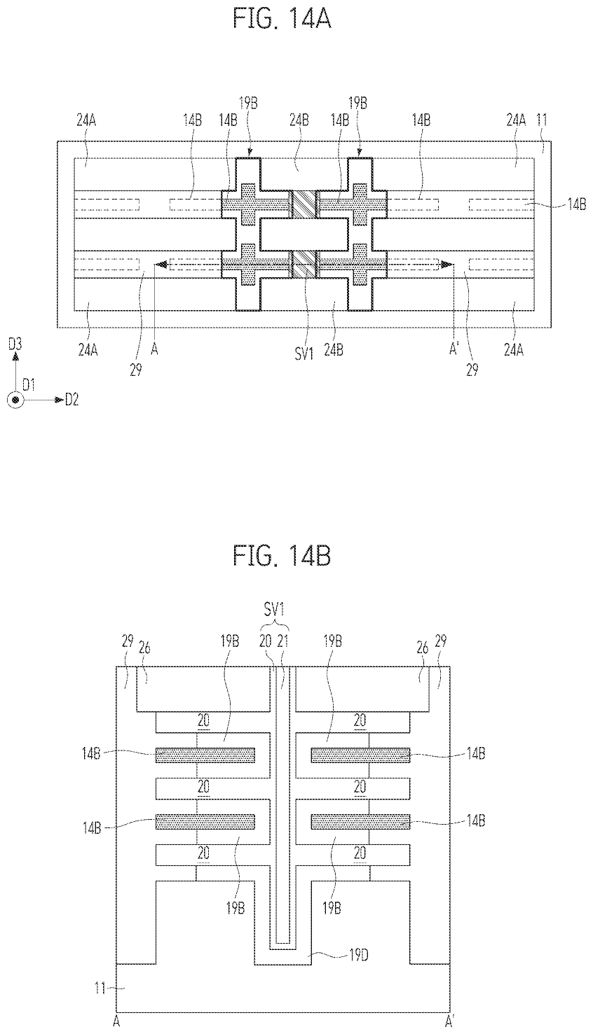

FIG. 14A is a plan view illustrating a method for forming vertical sacrificial structures 29, and FIG. 14B is a cross-sectional view taken along a line A-A′ shown in FIG. 14A.

Referring to FIGS. 14A and 14B, vertical sacrificial structures 29 filling the dielectric layer level recesses 28 and the initial vertical openings 27 may be formed. The vertical sacrificial structures 29 may include a sacrificial material. The vertical sacrificial structures 29 may include silicon oxide, silicon nitride, titanium nitride, amorphous carbon, or combinations thereof.

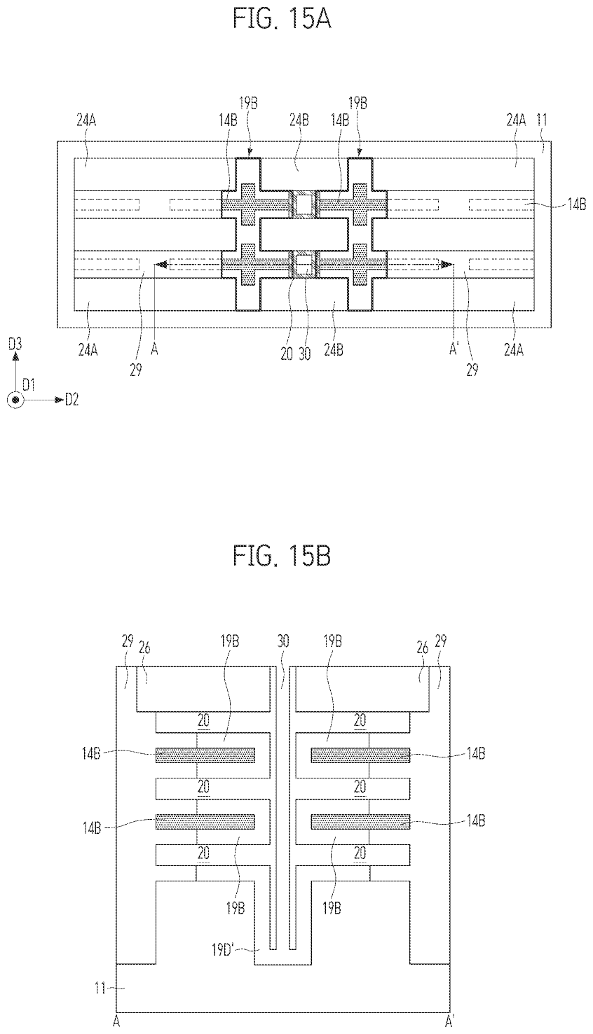

FIG. 15A is a plan view illustrating a method for forming a vertical level path 30, and FIG. 15B is a cross-sectional view taken along a line A-A′ shown in FIG. 15A.

Referring to FIGS. 15A and 15B, in order to form the vertical level path 30, the sacrificial pillars 21 of the first sacrificial pillar structure SV1 may be removed.

Subsequently, in order to form the lower level gap 19D′, the dummy dielectric layer 19D below the vertical level path 30 may be removed.

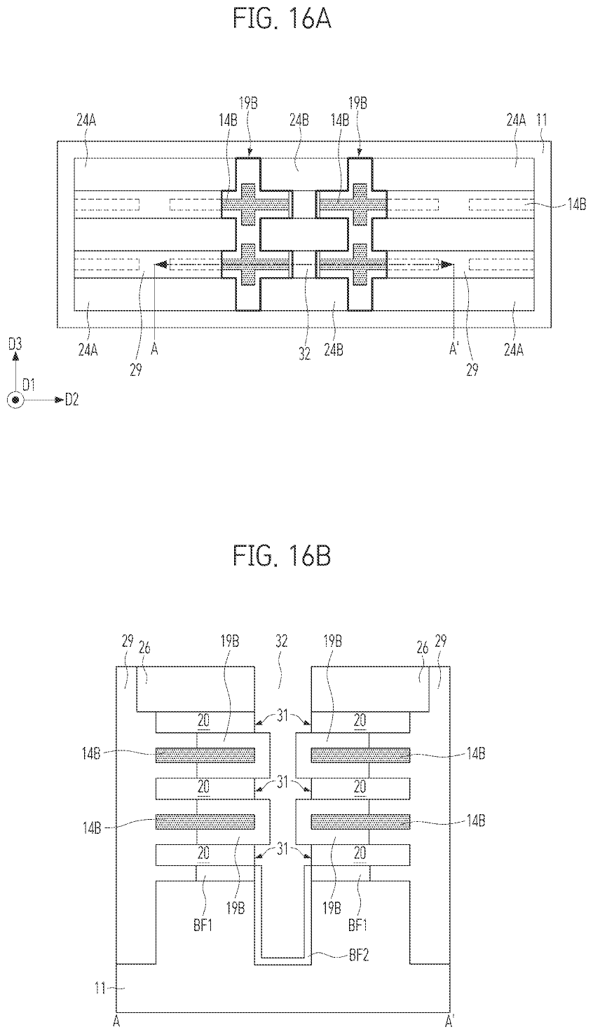

FIG. 16A is a plan view illustrating a method for forming first hole-type vertical openings 32, and FIG. 16B is a cross-sectional view taken along a line A-A′ shown in FIG. 16A.

Referring to FIGS. 16A and 16B, in order to form the first hole-type vertical openings 32, the second dielectric layers 20 may be cut 31 through the vertical level path 30.

Subsequently, a first passivation layer BF1 filling the lower level gap 19D′ may be formed. The first passivation layer BF1 may include silicon oxide. Forming the first passivation layer BF1 may include depositing silicon oxide that fills the lower level gap 19D′ and etching the silicon oxide. Subsequently, a second passivation layer BF2 may be formed in the lower region of the first hole-type vertical openings 32. For example, the surface of the lower structure 11 may be oxidized to form the second passivation layer BF2.

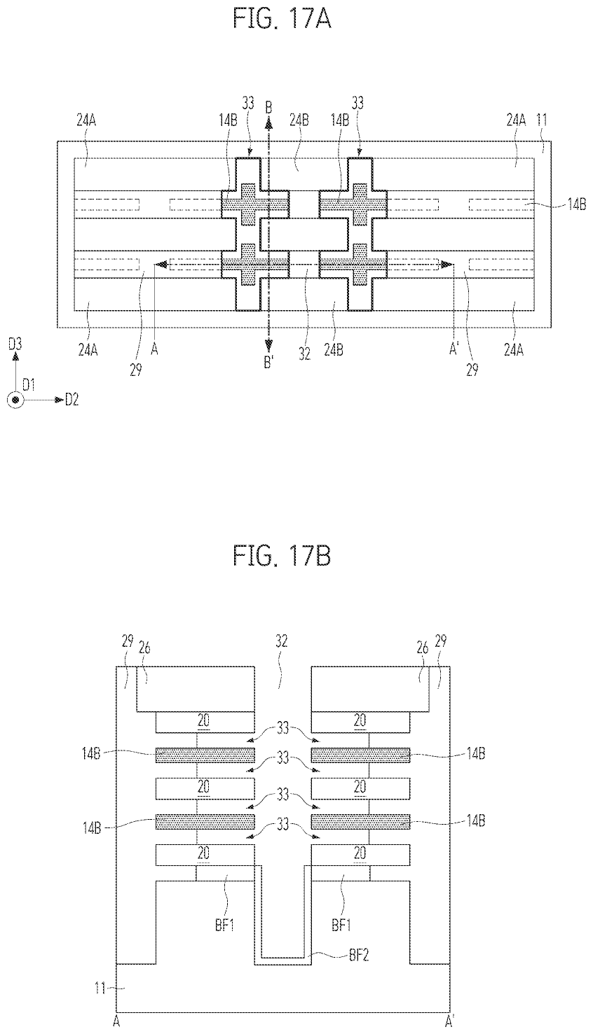

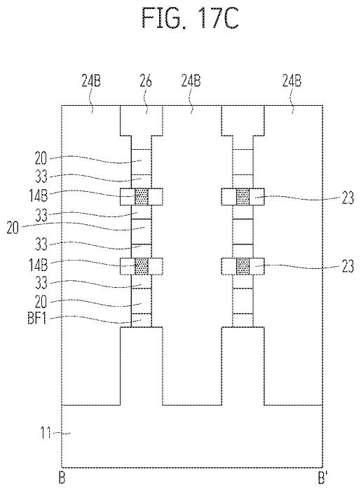

FIG. 17A is a plan view illustrating a method for forming the horizontal level recesses 33, and FIG. 17B is a cross-sectional view taken along a line A-A′ shown in FIG. 17A. FIG. 17C is a cross-sectional view taken along a line B-B′ shown in FIG. 17A. In some embodiments, the horizontal level recesses 33 may be lateral level recesses.

Referring to FIGS. 17A to 17C, the first dielectric layer patterns 19B may be removed through the first hole-type vertical openings 32 to form the horizontal level recesses 33. Portions of the horizontal layers 14B may be exposed by the horizontal level recesses 33. Referring back to FIG. 17C, the horizontal level recesses 33 may be disposed between the second dielectric layer 20 and the horizontal layer 14B. Two horizontal level recesses 33 may face each other with one horizontal layer 14B interposed therebetween.

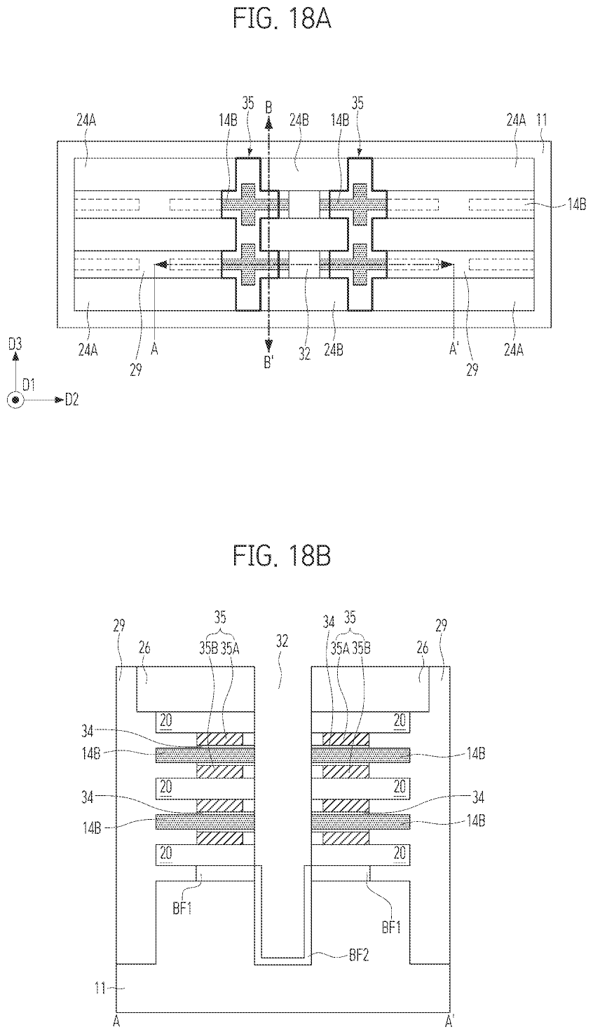

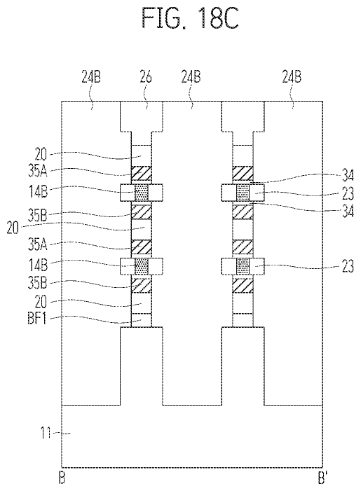

FIG. 18A is a plan view illustrating a method for forming the horizontal conductive lines 35, and FIG. 18B is a cross-sectional view taken along a line A-A′ shown in FIG. 18A. FIG. 18C is a cross-sectional view taken along a line B-B′ shown in FIG. 18A.

Referring to FIGS. 18A to 18C, an inter-level dielectric layer 34 may be formed over the exposed portions of the horizontal layers 14B. The inter-level dielectric layer 34 may be referred to as a gate dielectric layer. The inter-level dielectric layer 34 may correspond to the inter-level dielectric layer GD as illustrated in FIGS. 1A to 3B.

The inter-level dielectric layer 34 may be formed by oxidizing the surfaces of the horizontal layers 14B. According to another embodiment of the present invention, the inter-level dielectric layer 34 may be formed by a deposition process of silicon oxide. The inter-level dielectric layer 34 may include silicon oxide, silicon nitride, a metal oxide, a metal oxynitride, a metal silicate, a high-k material, a ferroelectric material, an anti-ferroelectric material or a combination thereof. The inter-level dielectric layer 34 may include SiO₂, Si₃N₄, HfO₂, Al₂O₃, ZrO₂, AlON, HfON, HfSIO, HfSION, or a combination thereof.

Subsequently, horizontal conductive lines 35 filling the horizontal level recesses 33 may be formed over the inter-level dielectric layer 34. In some embodiments, the horizontal conductive lines 35 may be extending laterally, e.g., horizontally and may be referred to as horizontal conductive lines. Forming the horizontal conductive lines 35 may include depositing a conductive material that fills the horizontal level recesses 33 over the inter-level dielectric layer 34 and etching back the conductive material. The horizontal conductive lines 35 may include a pair of first and second horizontal conductive lines 35A and 35B that are facing each other with the horizontal layer 14B interposed therebetween. The first and second horizontal conductive lines 35A and 35B may include a metal-based material, a semiconductor material, or a combination thereof. The first and second horizontal conductive lines 35A and 35B may include titanium nitride, tungsten, polysilicon, or a combination thereof. For example, the first and second horizontal conductive lines 35A and 35B may include a TiN/W stack in which titanium nitride and tungsten are sequentially stacked. The first and second horizontal conductive lines 35A and 35B may include an N-type work function material or a P-type work function material. The N-type work function material may have a low work function of approximately 4.5 eV or less, and the P-type work function material may have a high work function of approximately 4.5 eV or more.

The horizontal conductive line 35 may correspond to the second conductive line DWL as illustrated in FIGS. 1A to 1D, and the first and second horizontal conductive lines 35A and 35B may correspond to the upper horizontal line G1 and the lower horizontal line G2. As illustrated in FIGS. 1A to 1D, each of the first and second horizontal conductive lines 35A and 35B may have a cross shape, and may include a channel overlapping portion WLP and channel non-overlapping portions NOL. The terms “overlap” or “overlapping” are used herein to mean two structures are positioned or stacked over or below each other and share a common space in the stacking direction. Moreover “overlap′ or “overlapping” as used herein may mean a complete overlap or partial overlap unless further specified. Complete overlap or complete overlapping means that the two structures are entirely covering each other or sharing the same space entirely, with no part of either structure remaining separate from the other. Partial overlap or partial overlapping means that only a portion of one structure or object is overlapping with another.

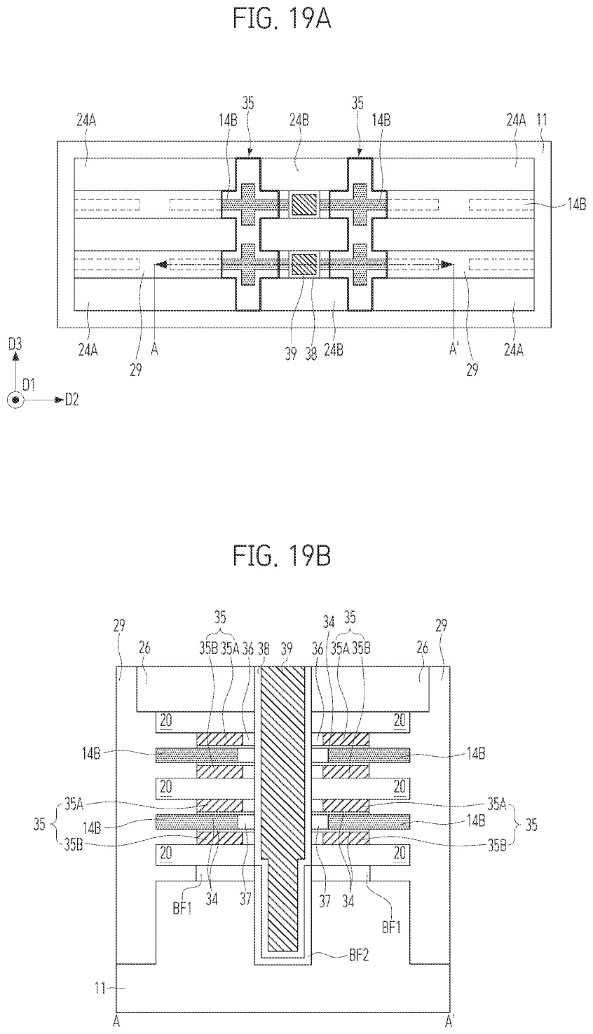

FIG. 19A is a plan view illustrating a method for forming the vertical conductive lines 39, and FIG. 19B is a cross-sectional view taken along a line A-A′ shown in FIG. 19A.

Referring to FIGS. 19A and 19B, a first capping layer 36 may be formed on one side of the horizontal conductive line 35. The first capping layer 36 may include silicon oxide, silicon nitride, silicon carbon oxide, an embedded air gap, or a combination thereof. A capping material may be deposited and etched back to form the first capping layer 36. While the first capping layer 36 is formed or after the first capping layer 36 is formed, a portion of the inter-level dielectric layer 34 may be removed to expose a first edge portion of each of the horizontal layers 14B.

Subsequently, the vertical conductive line 39 coupled to the first edge portion of each of the horizontal layers 14B may be formed. The vertical conductive line 39 may fill the first hole-type vertical openings 32. The vertical conductive line 39 may be commonly coupled to the horizontal layers 14B that are arranged in the first direction D1. The vertical conductive line 39 may include titanium nitride, tungsten, or a combination thereof. The vertical conductive line 39 may be referred to as a bit line or a vertical bit line. The vertical conductive lines 39 that are adjacent to each other in the third direction D3 may be spaced apart from each other by the second cell isolation layers 24B.

Before the vertical conductive line 39 is formed, a first doped region 37 and a first contact node 38 may be formed. The first doped region 37 may be formed in the first edge portions of the horizontal layers 14B. Forming the first doped region 37 may include depositing polysilicon that is doped with an N-type impurity, performing a heat treatment step, and removing the doped polysilicon. The first doped region 37 may include an impurity diffused from the doped polysilicon. According to another embodiment of the present invention, the first doped region 37 may be formed by a doping process of an impurity.

The first contact node 38 may include doped polysilicon. The first doped region 37 may include an impurity diffused from the first contact node 38. An ohmic contact layer, such as metal silicide, may be formed between the vertical conductive line 39 and the first contact node 38.

The vertical conductive line 39 may correspond to the first conductive line BL as illustrated in FIGS. 1A to 1D.

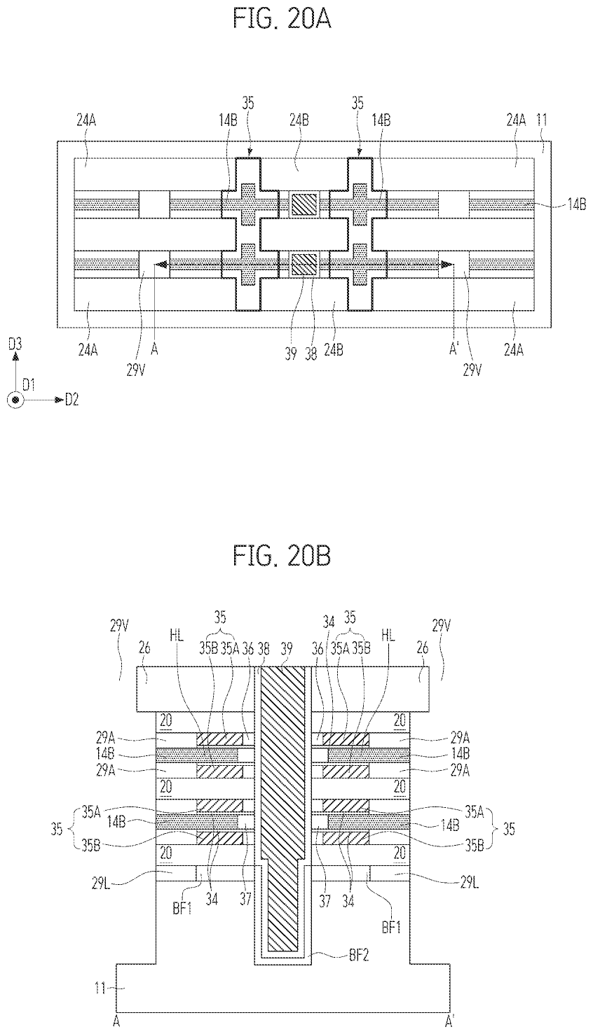

FIG. 20A is a plan view illustrating a method for forming preliminary second hole-type vertical openings 29V, and FIG. 20B is a cross-sectional view taken along a line A-A′ shown in FIG. 20A.

Referring to FIGS. 20A and 20B, a portion of the vertical sacrificial structure 29 may be removed to form preliminary second hole-type vertical openings 29V. First side surfaces of the horizontal layers 14B, that is, the second edge portion, may be exposed by the preliminary second hole-type vertical openings 29V. After the preliminary second hole-type vertical openings 29V are formed, a preliminary second capping layer 29A may be formed over the upper and lower surfaces of the horizontal layers 14B.

While the preliminary second capping layer 29A is formed, a lowermost level dielectric layer 29L may be formed over the side surfaces of the first passivation layers BF1 by removing a portion of the vertical sacrificial structure 29.

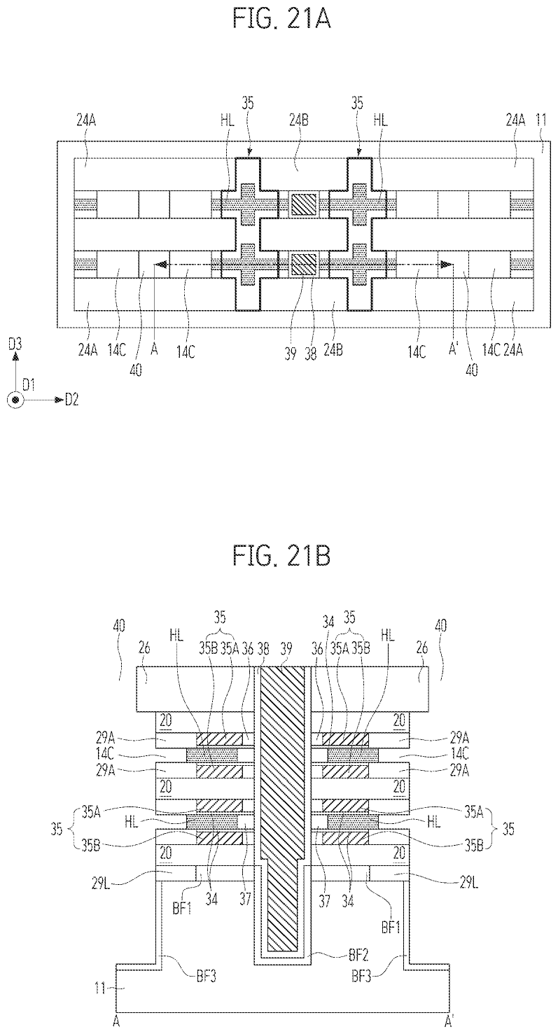

FIG. 21A is a plan view illustrating a method for forming the horizontal layers HL, and FIG. 21B is a cross-sectional view taken along a line A-A′ shown in FIG. 21A.

Referring to FIGS. 21A and 21B, a third passivation layer BF3 may be formed over the surface of the lower structure 11. The third passivation layer BF3 may include silicon oxide.

Subsequently, the second edge portions of the horizontal layers 14B may be laterally (e.g., horizontally) recessed (refer to a reference numeral 14C) in the second direction D2. As a result, the horizontal layers may remain as indicated by reference symbol ‘HL’.

After the horizontal layers HL are formed, the preliminary second hole-type vertical openings may be expanded as indicated by a reference numeral 40. Hereinafter, the expanded preliminary second hole-type vertical openings may be simply referred to as second hole-type vertical openings 40.

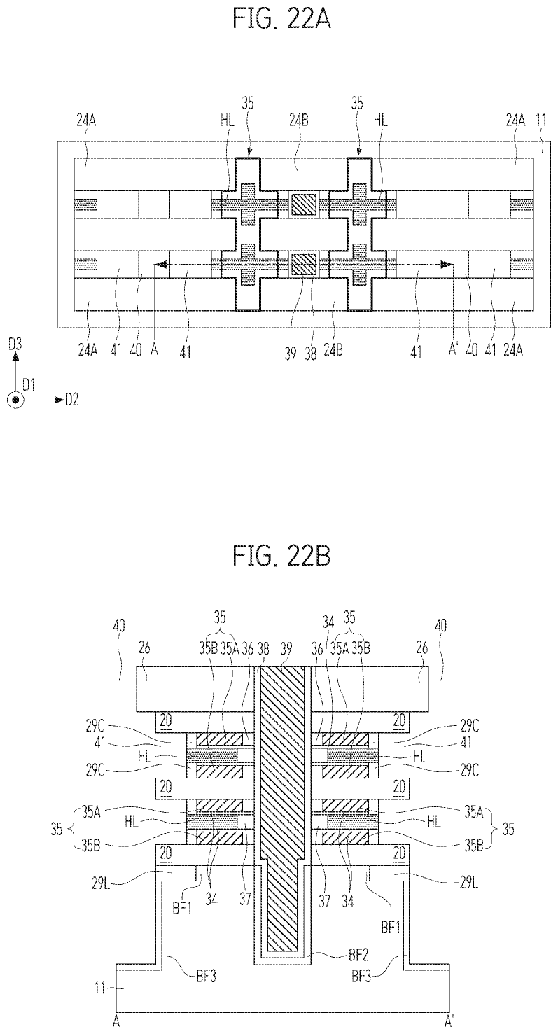

FIG. 22A is a plan view illustrating a method for forming the storage openings 41, and FIG. 22B is a cross-sectional view taken along a line A-A′ shown in FIG. 22A.

Referring to FIGS. 22A and 22B, in order to form the second capping layers 29C, the preliminary second capping layers 29A may be selectively recessed. The second capping layers 29C may include silicon oxide, silicon nitride, or a combination thereof.

After the second capping layers 29C are formed, storage openings 41 extending laterally, e.g., horizontally from the second hole-type vertical openings 40 may be formed. The storage openings 41 may be referred to as capacitor openings.

The horizontal layers HL may include a first edge and a second edge. The first edge may refer to a portion that is coupled to the first contact node 38 and the vertical conductive line 39, and the second edge may refer to a portion that is exposed by the storage openings 41.

The storage openings 41 may be disposed between the second dielectric layers 20. The second capping layers 29C may be disposed on the lower and upper portions of the horizontal layers HL, respectively.

As described above, forming the horizontal layers HL and the storage openings 41 may include forming the second hole-type vertical openings 40, recessing the horizontal layers 14B, and forming the second capping layer 29C.

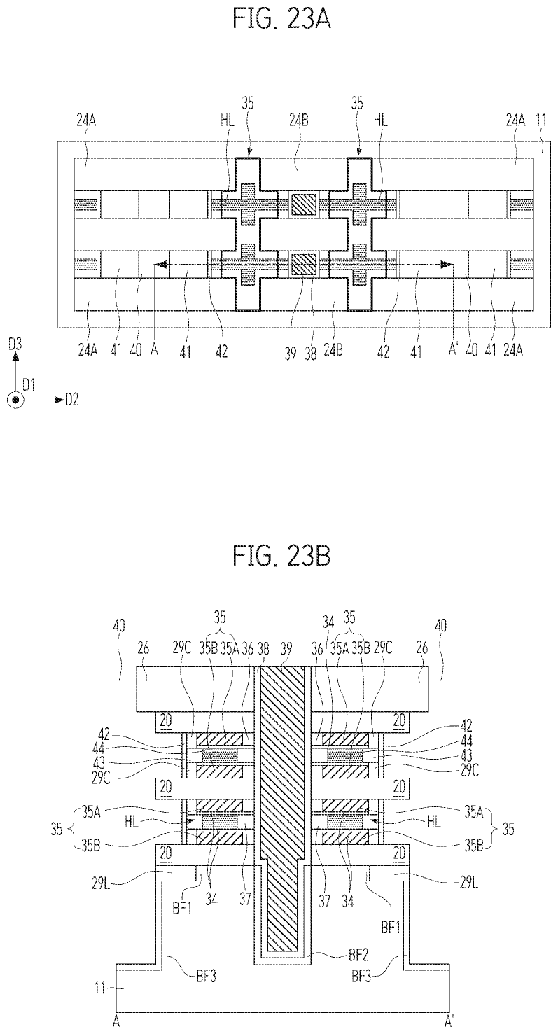

FIG. 23A is a plan view illustrating a method for forming second contact nodes 42, and FIG. 23B is a cross-sectional view taken along a line A-A′ shown in FIG. 23A.

Referring to FIGS. 23A and 23B, second doped regions 43 may be formed in the second edges of the horizontal layers HL, respectively. Forming the second doped regions 43 may include depositing polysilicon that is doped with an N-type impurity, performing a heat treatment, and removing the doped polysilicon. The second doped regions 43 may include an impurity diffused from the doped polysilicon. According to another embodiment of the present invention, the doped polysilicon may remain after the heat treatment.

Subsequently, second contact nodes 42 may be formed over the second edges of the horizontal layers HL. The second contact nodes 42 may include doped polysilicon. The second doped regions 43 may include an impurity diffused from the second contact nodes 42.

Each of the horizontal layers HL may include a first doped region 37, a second doped region 43, and a channel 44 that are laterally, e.g., horizontally disposed in the second direction D2. The channels 44 may be defined between the first doped regions 37 and the second doped regions 43. The channels 44 may vertically overlap with the horizontal conductive lines 35. As illustrated in FIGS. 1A to 1D, the horizontal layers HL may have a cross shape, and the channels 44 may also have a cross shape.

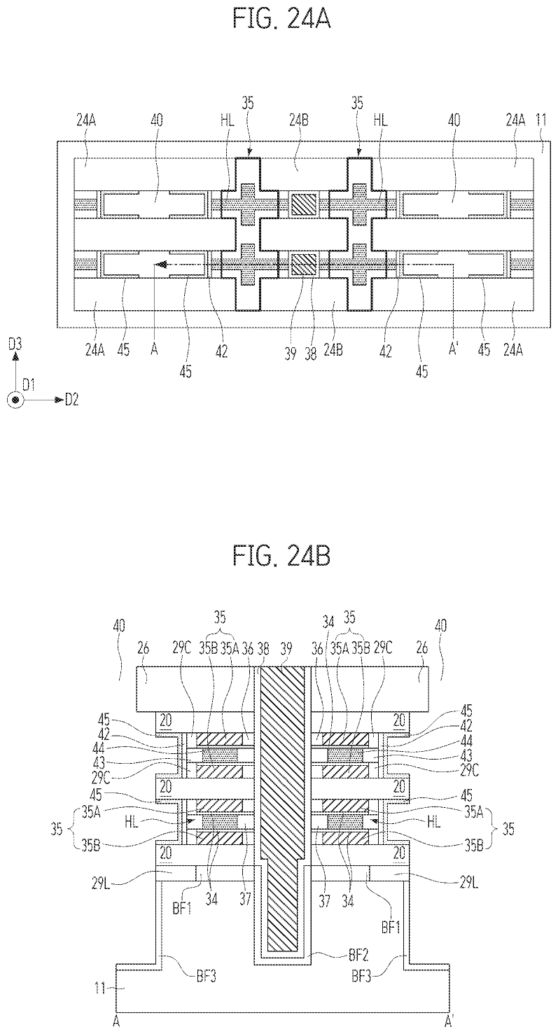

FIG. 24A is a plan view illustrating a method for forming the first electrodes 45, and FIG. 24B is a cross-sectional view taken along a line A-A′ shown in FIG. 24A.

Referring to FIGS. 24A and 24B, the first electrodes 45 of the data storage element may be formed over the second contact nodes 42. The first electrodes 45 may have a horizontally oriented cylindrical shape. The first electrodes 45 may be respectively disposed in the storage openings 41. The first electrodes 45 that are disposed adjacent to each other in the second direction D2 may be spaced apart from each other by the second hole-type vertical openings 40. The first electrodes 45 that are disposed adjacent to each other in the third direction D3 may be spaced apart from each other by the first cell isolation layers 24A.

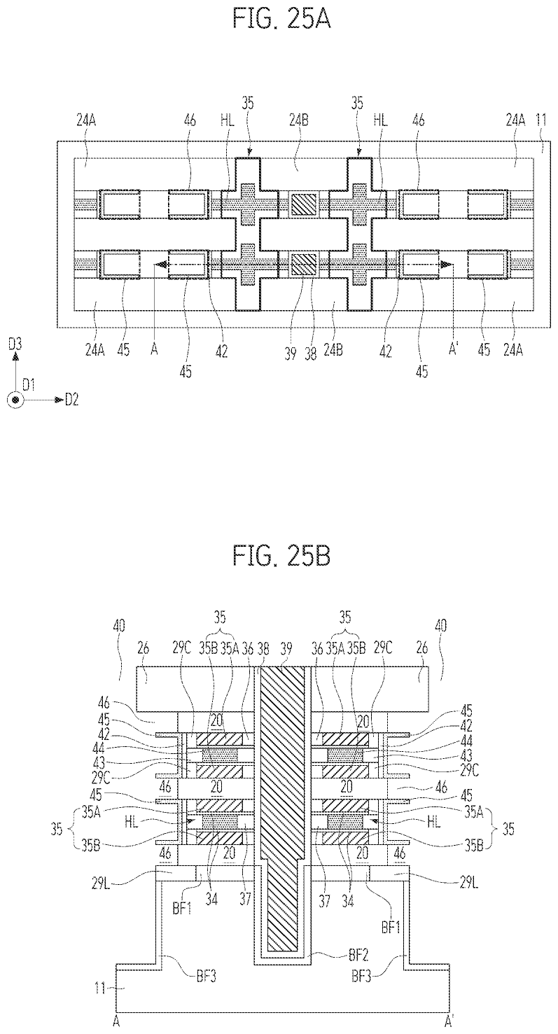

FIG. 25A is a plan view illustrating a method of exposing the outer walls of the first electrodes 45, and FIG. 25B is a cross-sectional view taken along a line A-A′ shown in FIG. 25A.

Referring to FIGS. 25A and 25B, the second dielectric layers 20 may be horizontally recessed (a reference numeral ‘46’). As a result, the outer walls of the first electrodes 45 may be exposed. The recessed second dielectric layers 20 may correspond to the inter-cell dielectric layers IL as illustrated in FIG. 3B.

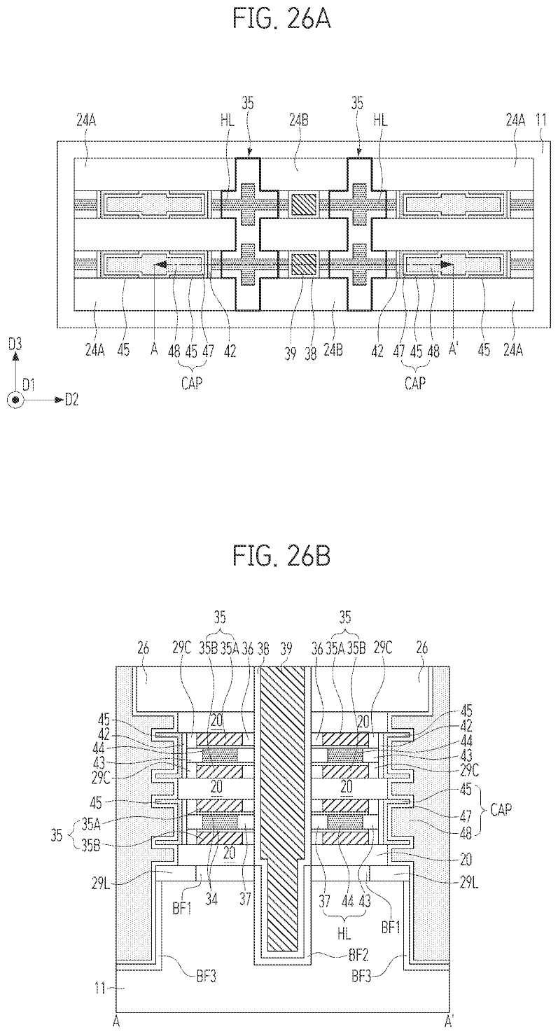

FIG. 26A is a plan view illustrating a method for forming the dielectric layer 47 and the second electrode 48, and FIG. 26B is a cross-sectional view taken along a line A-A′ shown in FIG. 26A.

Referring to FIGS. 26A and 26B, a dielectric layer 47 and a second electrode 48 may be sequentially formed over the first electrodes 45. The first electrode 45, the dielectric layer 47, and the second electrode 48 may become a data storage element CAP.

Each first electrode 45 may include an inner space and a plurality of outer surfaces, and the inner space of the first electrode 45 may include a plurality of inner surfaces. The outer surfaces of the first electrode 45 may include a vertical outer surface and a plurality of horizontal outer surfaces. The vertical outer surface of the first electrode 45 may extend vertically in the first direction D1, and the horizontal outer surface of the first electrode 45 may horizontally extend in the second direction D2 or the third direction D3. The inner space of the first electrode 45 may be a three-dimensional space. The dielectric layer 47 may conformally cover or be on the inner and outer surfaces of the first electrode 45. The second electrode 48 may be disposed in the inner space of the first electrode 45 over the dielectric layer 47. Some of the outer surfaces of the first electrode 45 may be electrically connected to the second doped region 43 of the horizontal layer HL.

The first electrode 45 may have a cylindrical shape. The cylindrical shape of the first electrode 45 may include cylindrical inner surfaces and cylindrical outer surfaces. Some of the outer surfaces of the cylinder of the first electrode 45 may be electrically connected to the second doped region 43 of the horizontal layer HL. A dielectric layer 47 and a second electrode 48 may be disposed on the inner surfaces of the cylindrical space of the first electrode 45. The second electrode 48 may extend vertically in the first direction D1.

The first electrode 45 and the second electrode 48 may include a metal, a noble metal, a metal nitride, a conductive metal oxide, a conductive noble metal oxide, a metal carbide, a metal silicide, or a combination thereof. For example, the first electrode 45 and the second electrode 48 may include titanium (Ti), titanium nitride (TIN), tantalum (Ta), tantalum nitride (TaN), tungsten (W), or tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode 48 may include a combination of a metal-based material and a silicon-based material. For example, the second electrode 48 may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material that fills the inner space of the first electrode 45, and titanium nitride (TiN) may serve as the second electrode 48 of the data storage element CAP, and tungsten nitride may be a low-resistance material.

The dielectric layer 47 may be referred to as a capacitor dielectric layer or a memory layer. The dielectric layer 47 may include silicon oxide, silicon nitride, a high-k material, a ferroelectric material, an antiferroelectric material, or a combination thereof. The dielectric layer 47 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). The dielectric layer 45 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, an HA (HfO₂/Al₂O₃) stack, an HAH (HfO₂/Al₂O₃/HfO₂) stack, a HAHA (HfO₂/Al₂O₃/HfO₂/Al₂O₃) stack, or a HAHAH (HfO₂/Al₂O₃/HfO₂/Al₂O₃/HfO₂) stack.

According to another embodiment of the present invention, an interface control layer for improving leakage current may be further formed between the first electrode 45 and the dielectric layer 47. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 45 and the dielectric layer 47.

According to the description referring to FIGS. 4A to 26B, the method for fabricating a semiconductor device in accordance with an embodiment of the present invention may include forming preliminary horizontal layers 14A vertically stacked in the first direction D1 over the lower structure 11 and extending laterally, e.g., horizontally in the second direction D2 crossing the first direction D1, forming trimming target layers respectively surrounding the preliminary horizontal layers 14A, forming horizontal layers 14B by trimming the preliminary horizontal layers 14A in the third direction D3 crossing the second direction D2, forming trimmed target layers by trimming the trimming target layers in the third direction D3, and replacing the trimmed target layers with horizontal conductive lines 35. The trimming target layers may correspond to the first dielectric layers 19 as illustrated in FIGS. 8A to 8C. The trimmed target layers may correspond to the trimmed first dielectric layers 19A as illustrated in FIGS. 10A and 10B.

According to the above-described embodiment of the present invention, since the cross-shaped horizontal layer HL is formed, the channel width and the bridge between the memory cells may be improved.

Also, since the operation of forming the trimmed target layers 19A by trimming the trimming target layers 19 and the operation of replacing the trimmed target layers 19A with the horizontal conductive lines 35 are included, the bridge between the horizontal conductive lines 35 that are stacked vertically may be improved.

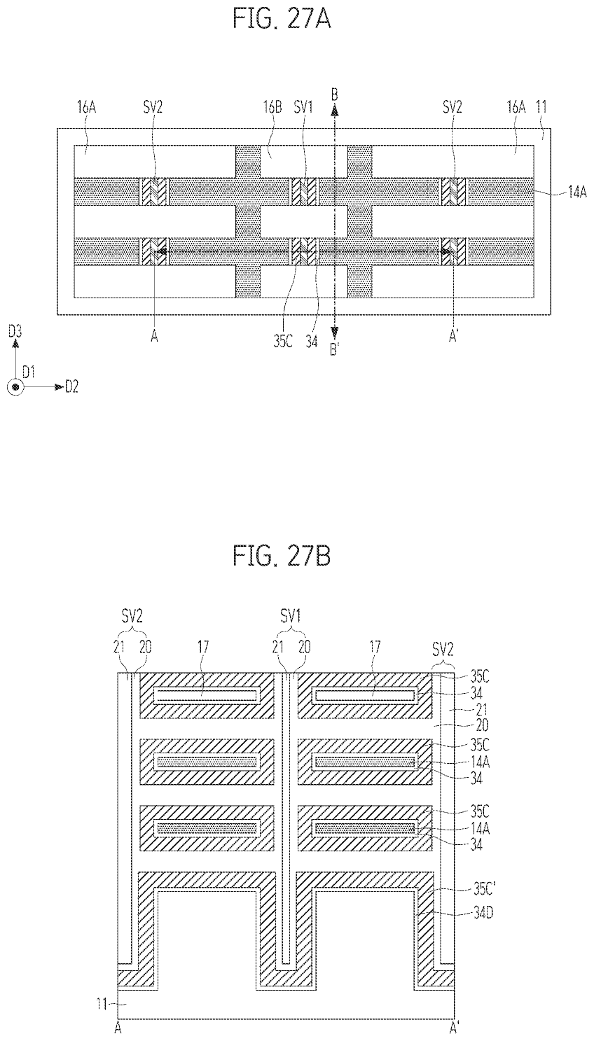

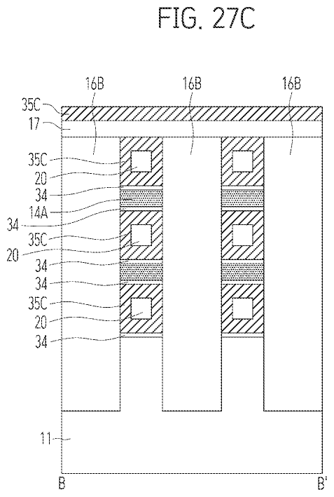

FIGS. 27A to 38B are cross-sectional views illustrating a method for fabricating a semiconductor device in accordance with another embodiment of the present invention. FIGS. 27A to 36B illustrate another embodiment of a method for forming the horizontal conductive line 35.

As a result of performing a series of the processes illustrated in FIGS. 4A to 7B, the preliminary horizontal layers 14A and the horizontal recesses 18 may be formed.

FIG. 27A is a plan view illustrating a method for forming the inter-level dielectric layer 34 and the horizontal conductive layer 35C, and FIG. 27B is a cross-sectional view taken along a line A-A′ shown in FIG. 27A. FIG. 27C is a cross-sectional view taken along a line B-B′ shown in FIG. 27A.

Referring to FIGS. 27A to 27C, inter-level dielectric layers 34 may be formed to fully cover or be on the preliminary horizontal layers 14A. The inter-level dielectric layer 34 may be referred to as a gate dielectric layer. The inter-level dielectric layer 34 may be referred to as a horizontal layer-side dielectric layer. The inter-level dielectric layer 34 may include silicon oxide, silicon nitride, a metal oxide, a metal oxynitride, a metal silicate, a high-k material, a ferroelectric material, an anti-ferroelectric material or a combination thereof. The inter-level dielectric layer 34 may include SiO₂, Si₃N₄, HfO₂, Al₂O₃, ZrO₂, AlON, HfON, HfSIO, HfSION, HfZrO, or a combination thereof.

The inter-level dielectric layer 34 may be formed by oxidizing the surfaces of the preliminary horizontal layers 14A. According to another embodiment of the present invention, the inter-level dielectric layer 34 may be formed by a deposition process of silicon oxide.

While the inter-level dielectric layer 34 is formed, a dummy inter-level dielectric layer 34D may be formed over the surface of the lower structure 11. The inter-level dielectric layer 34 and the dummy inter-level dielectric layer 34D may be formed of the same material.

Subsequently, a horizontal conductive layer 35C may be formed over the inter-level dielectric layers 34. The horizontal conductive layer 35C may include a metal-based material, a semiconductor material, or a combination thereof. The horizontal conductive layer 35C may include titanium nitride, tungsten, polysilicon, or a combination thereof. For example, the horizontal conductive layer 35C may include a TiN/W stack in which titanium nitride and tungsten are sequentially stacked. The horizontal conductive layer 35C may include an N-type work function material or a P-type work function material. The N-type work function material may have a low work function of approximately 4.5 eV or less, and the P-type work function material may have a high work function of approximately 4.5 eV or more. While the horizontal conductive layer 35 is formed, a dummy horizontal conductive layer 35C′ may be formed over the dummy inter-level dielectric layer 34D. The horizontal conductive layer 35C and the dummy horizontal conductive layer 35C′ may be formed of the same material.

Subsequently, a second dielectric layer 20 may be formed over the horizontal conductive layers 35C. The second dielectric layer 20 may fill between the horizontal conductive layers 35C that are disposed vertically adjacent to each other. The second dielectric layer 20 may include silicon oxide. Portions of the second dielectric layer 20 may be conformally formed over the surfaces of the first and second sacrificial vertical openings V1 and V2. The horizontal recesses (18 in FIGS. 7B and 7C) may be filled with the horizontal conductive layer 35C and the second dielectric layer 20.

Subsequently, sacrificial pillars 21 may be formed over the second dielectric layer 20 that is disposed in the first and second sacrificial vertical openings V1 and V2. The sacrificial pillars 21 may be of a sacrificial material and may include amorphous carbon. According to another embodiment of the present invention, a pillar capping layer may be further formed over the sacrificial pillars 21. The pillar capping layer may include a metal-based material. The pillar capping layer may include titanium nitride. Forming the sacrificial pillars 21 may include depositing a sacrificial material and planarizing the sacrificial material. The planarization operation for forming the sacrificial pillars 21 may be performed until the uppermost level horizontal conductive layer 35C is exposed. Subsequently, the uppermost-level second dielectric layers 20 may also be planarized until the uppermost-level horizontal conductive layer 35C is exposed. The sacrificial pillars 21 may not be formed between the vertically stacked horizontal conductive layers 35C.

The second dielectric layer 20 and the sacrificial pillars 21 may form first and second sacrificial pillar structures SV1 and SV2 that fill the first and second sacrificial vertical openings V1 and V2. The first sacrificial pillar structure SV1 may fill the first sacrificial vertical openings V1, and the second sacrificial pillar structure SV2 may fill the second sacrificial vertical openings V2. According to another embodiment of the present invention, the first and second sacrificial pillar structures SV1 and SV2 may include a dielectric material, a carbon-containing material, a metal-based material, or a combination thereof. According to another embodiment of the present invention, the first and second sacrificial pillar structures SV1 and SV2 may include silicon oxide, silicon nitride, titanium nitride, amorphous carbon, or a combination thereof. From the perspective of a top view, the first sacrificial pillar structure SV1 and the second sacrificial pillar structure SV2 may be sacrificial pillars.

Referring back to FIG. 27C, horizontal conductive layers 35C may be formed between the preliminary horizontal layers 14A, and second dielectric layers 20 may be disposed inside the horizontal conductive layers 35C. The horizontal conductive layers 35C may surround the second dielectric layers 20. The horizontal conductive layers 35C may include a first surrounding portion and a second surrounding portion. The first surrounding portion may surround the preliminary horizontal layers 14A in the A-A′ direction, and the second surrounding portion may surround the second dielectric layers 20 in the B-B′ direction.

Through a series of the processes illustrated in FIGS. 4A to 7C and 27A to 27C as described above, the sub-stacks of the stack body SB may be replaced with cell molds. The first layers 12A, the second layers 13 and the third layers 12B may be replaced with the horizontal conductive layers 35C and the second dielectric layers 20. The fourth layers 14 may become preliminary horizontal layers 14A by a recess process. The horizontal conductive layers 35C may be referred to as trimming target layers.

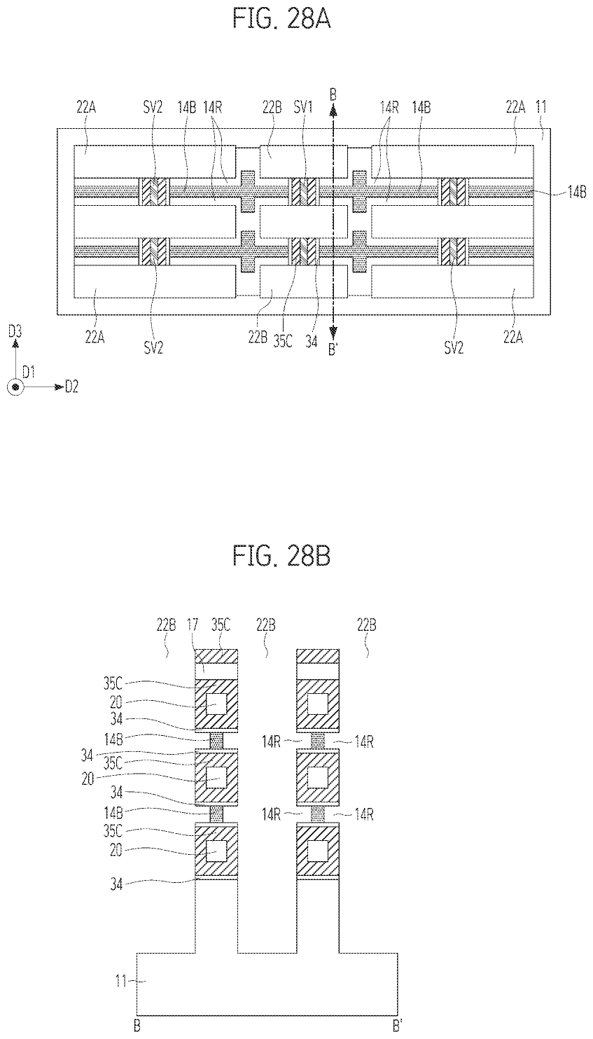

FIG. 28A is a plan view illustrating a method for forming the cell isolation openings 22A and 22B and the horizontal layers 14B, and FIG. 28B is a cross-sectional view taken along a line B-B′ shown in FIG. 28A.

Referring to FIGS. 28A and 28B, the cell isolation openings 22A and 22B may be formed by removing the first and second sacrificial isolation layers 16A and 16B. While the first and second sacrificial isolation layers 16A and 16B are removed, the first and second sacrificial pillar structures SV1 and SV2 may be covered by a mask layer. The side surfaces of the preliminary horizontal layers 14A and the horizontal conductive layers 35C may be exposed by the cell isolation openings 22A and 22B in the B-B′ direction.

Subsequently, the side surfaces of the preliminary horizontal layers 14A may be trimmed in the second and third directions D2 and D3 through the cell isolation openings 22A and 22B. As a result, the trimmed horizontal layers 14B may be formed. Horizontal layer level gaps 14R may be formed over the side surfaces of the horizontal layers 14B. The horizontal layer level gap 14R and the horizontal layers 14B may be disposed between the inter-level dielectric layers 34. The horizontal layers 14B may be referred to as ‘trimmed horizontal layer patterns’.

While the horizontal layers 14B are formed, the surface of the lower structure 11, for example, the bottom surface of the cell isolation openings 22A and 22B may be expanded.

The horizontal layers 14B may be disposed between the first sacrificial pillar structure SV1 and the second sacrificial pillar structure SV2 in the second direction D2. From the perspective of a top view, the horizontal layers 14B may have a cross shape. The horizontal layers 14B may have a cross shape which is smaller in size than the preliminary horizontal layers 14A. The preliminary horizontal layers 14A may have a shape in which a plurality of cross shapes are merged, and the horizontal layers 14B may have a shape in which the cross shapes are individually separated in the third direction D3. The horizontal layer level gap 14R may be formed between the horizontal layers 14B that are disposed in the third direction D3. The first and second sacrificial pillar structures SV1 and SV2 may be disposed between the horizontal layers 14B in the second direction D2.

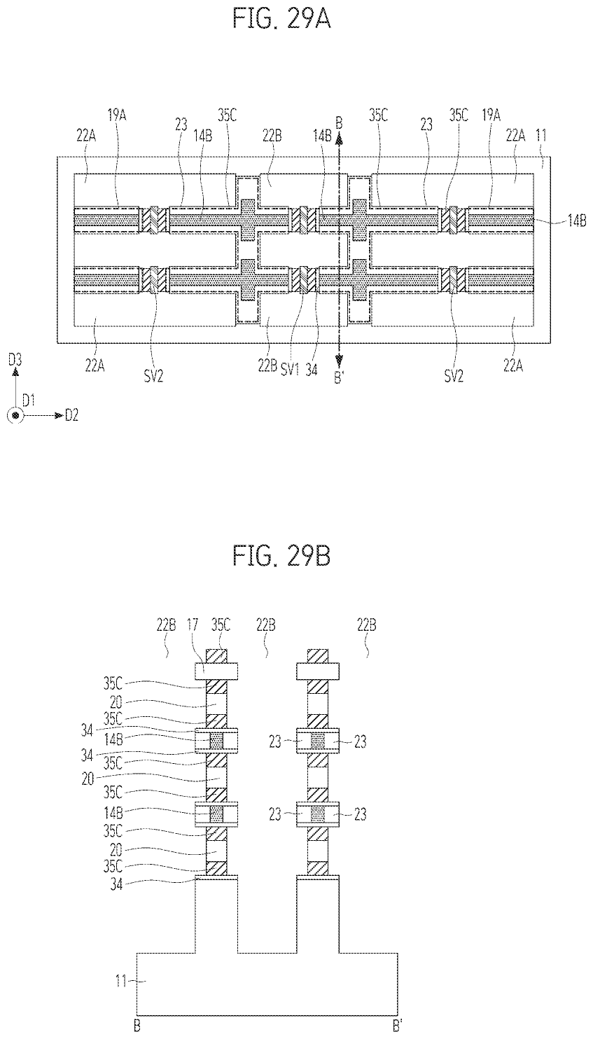

FIG. 29A is a plan view illustrating the formation of horizontal layer level spacers 23 and the recesses of the horizontal conductive layers, and FIG. 29B is a cross-sectional view taken along a line B-B′ shown in FIG. 29A.

Referring to FIGS. 29A and 29B, horizontal layer level spacers 23 may be formed over the side surfaces of the horizontal layers 14B. Forming the horizontal layer level spacers 23 may include forming a spacer material on the side surfaces of the horizontal layers 14B and etching the spacer material. The horizontal layer level spacers 23 may include a dielectric material, for example, silicon oxide. The horizontal layer level spacers 23 may fill the horizontal layer level gaps 14R. The horizontal layers 14B disposed in the third direction D3 may be separated from each other by the horizontal layer level spacers 23.

Subsequently, portions of the horizontal conductive layers 35C may be laterally (e.g., horizontally) trimmed through the cell isolation openings 22A and 22B. Accordingly, from the perspective of B-B′, a pair of horizontal conductive layers 35C may be disposed between the horizontal layers 14B, and one second dielectric layer 20 may be disposed between the horizontal conductive layers 35C of a pair.

According to FIGS. 28A to 29B, the width of the horizontal conductive layers 35C in the third direction D3 between the cell isolation openings 22A and 22B may be greater than the width of the horizontal layers 14B. That is, the trimming depth of the horizontal conductive layers 35C in the third direction D3 may be smaller than the trimming depth of the preliminary horizontal layers 14A.

A pair of the horizontal conductive layers 35C may vertically overlap with one horizontal layer 14B. The trimmed horizontal conductive layers 35C may be referred to as trimmed horizontal conductive layers.

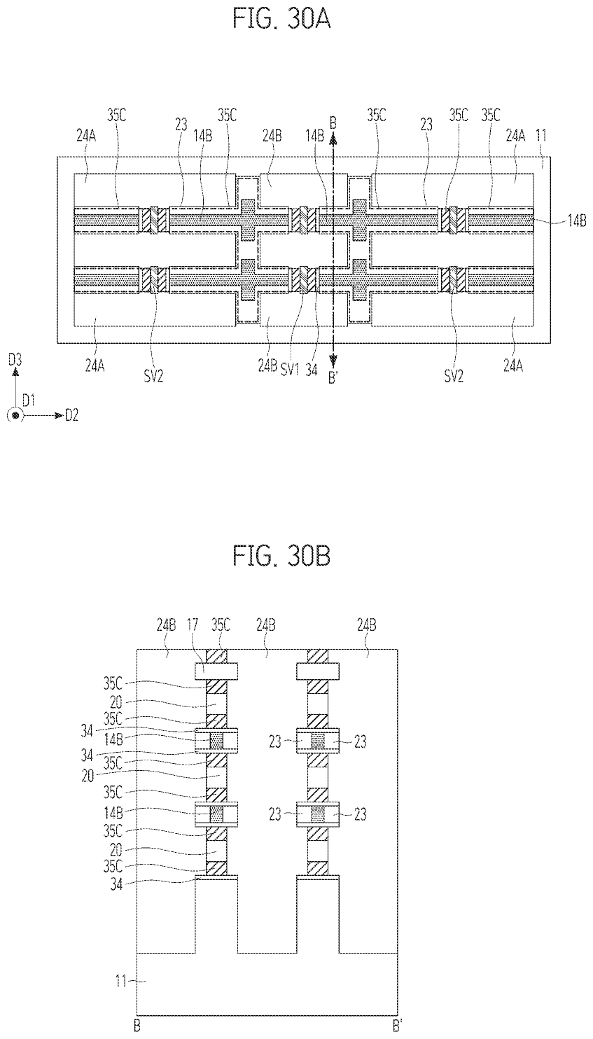

FIG. 30A is a plan view illustrating a method for forming the cell isolation layers 24A and 24B, and FIG. 30B is a cross-sectional view taken along a line B-B′ shown in FIG. 30A. FIG. 30A may be a plan view of a horizontal conductive layer 35C level illustrating a method for forming the cell isolation layers 24A and 24B.

Referring to FIGS. 30A and 30B, the cell isolation layers 24A and 24B filling the cell isolation openings 22A and 22B may be formed. The cell isolation layers 24A and 24B may include first cell isolation layers 24A and second cell isolation layers 24B. The first cell isolation layers 24A and the second cell isolation layers 24B may include the same material. The first cell isolation layers 24A and the second cell isolation layers 24B may be formed of a dielectric material. For example, the first cell isolation layers 24A and the second cell isolation layers 24B may include silicon oxide, silicon nitride, silicon carbon oxide, silicon carbon nitride, or a combination thereof. From the perspective of a top view, the outermost materials of the first cell isolation layers 24A and the second cell isolation layers 24B may include silicon carbon oxide.

Forming the first cell isolation layers 24A and the second cell isolation layers 24B may include forming a cell isolation material that fills the cell isolation openings 22A and 22B and planarizing the cell isolation material and the uppermost first dielectric layer 19A to expose the surface of the hard mask layer pattern 17. The first cell isolation layers 24A and the second cell isolation layers 24B may have different sizes or different volumes. The first cell isolation layers 24A and the second cell isolation layers 24B may include a double structure of silicon oxide and silicon carbon oxide. For example, silicon carbon oxide may be deposited after silicon oxide is deposited. According to another embodiment of the present invention, the first and second cell isolation layers 24A and 24B may include an embedded air gap, and the embedded air gap may be provided when silicon carbon oxide is deposited. A second sacrificial pillar structure SV2 may be disposed between the first cell isolation layers 24A in the third direction D3, and a first sacrificial pillar structure SV1 may be disposed between the second cell isolation layers 24B in the third direction D3. The first and second cell isolation layers 24A and 24B may extend vertically in the first direction D1.

The first and second cell isolation layers 24A and 24B may correspond to the cell isolation layers ISOA and ISOB as illustrated in FIGS. 2 to 3B.

The first and second cell isolation layers 24A and 24B and the horizontal conductive layers 35C may directly contact each other. Horizontal layer level spacers 23 may be disposed between the horizontal layers 14B and the first and second cell isolation layers 24A and 24B.

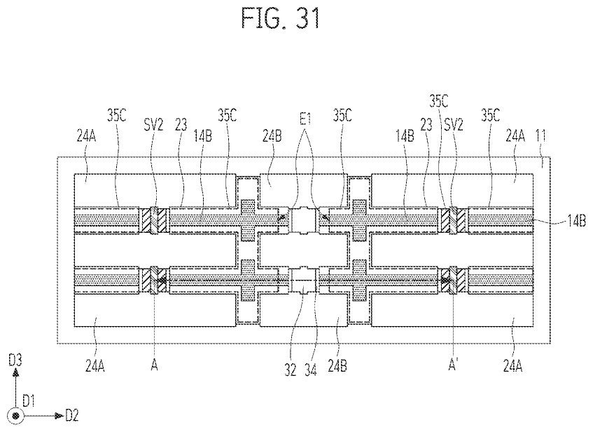

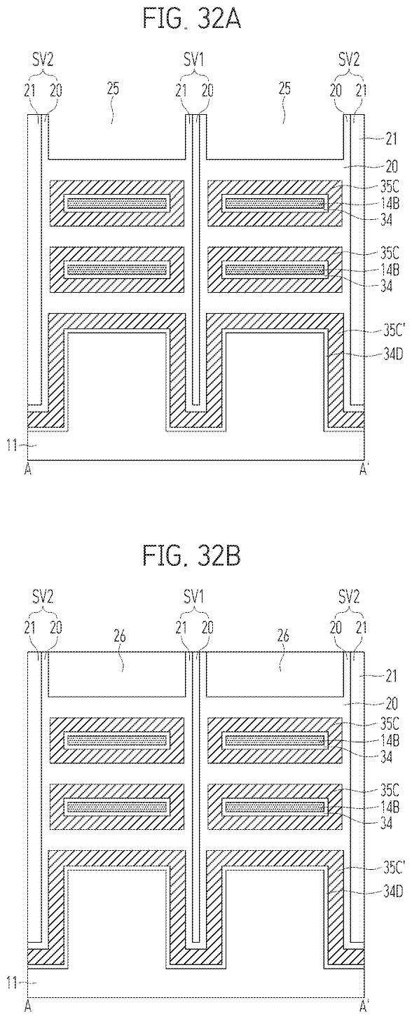

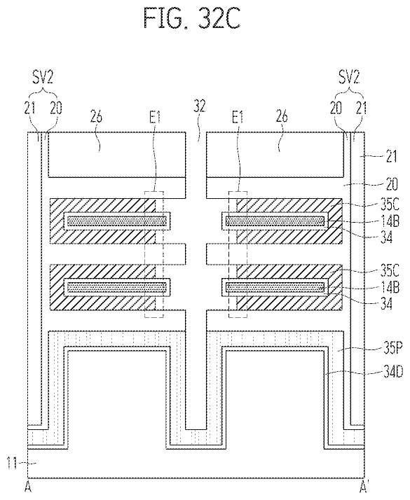

FIG. 31 is a plan view illustrating a method for forming the first hole-type vertical openings 32, and FIGS. 32A to 32C are cross-sectional views taken along a line A-A′ shown in FIG. 31.

First, referring to FIG. 32A, the hard mask layer pattern 17 and the uppermost level horizontal conductive layer 35C may be removed to form hard mask layer level recesses 25.

Referring to FIG. 32B, a top dielectric layer 26 filling the hard mask layer level recesses 25 may be formed. The top dielectric layer 26 may include silicon oxide.

Referring to FIG. 32C, in order to form the first hole-type vertical openings 32, the sacrificial pillars 21 of the first sacrificial pillar structure SV1 may be removed. Subsequently, the second dielectric layer 20 on the bottom surface of the first hole-type vertical openings 32 may be etched to expose the dummy horizontal conductive layer 35C′. Subsequently, the dummy horizontal conductive layer 35C′ may be replaced with the lower passivation layer 35P. Forming the lower passivation layer 35P may include forming a lower level gap by removing the dummy horizontal conductive layer 35C′ and filling the lower level gap with the lower passivation layer 35P. The lower passivation layer 35P may include silicon oxide. A dummy inter-level dielectric layer 34D may remain between the lower passivation layer 35P and the lower structure 11.

Subsequently, the second dielectric layers 20 may be horizontally cut through the first hole-type vertical openings 32.

Subsequently, first-side surfaces of the horizontal conductive layer 35C may be selectively recessed from the first hole-type vertical openings 32. Portions of the inter-level dielectric layer 34 may be exposed by the partial recess of the horizontal conductive layer 35C.

The recess process of the horizontal conductive layers 35C may be simply referred to as a first side recess process of the horizontal conductive layers 35C.

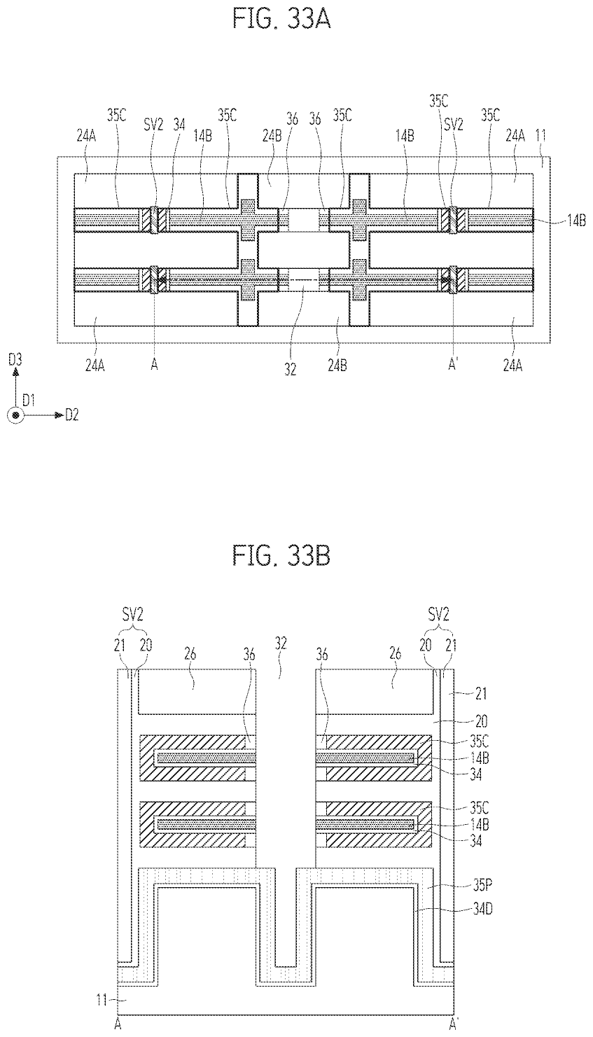

FIG. 33A is a plan view illustrating a method for forming the first capping layer 36, and FIG. 33B is a cross-sectional view taken along a line A-A′ shown in FIG. 33A. FIG. 33A may be a plan view of the horizontal conductive layer 35C level illustrating a method for forming the first capping layer 36.

Referring to FIGS. 33A and 33B, the first capping layer 36 may be formed over the recessed side surfaces of the horizontal conductive layers 35C. The first capping layer 36 may include silicon oxide, silicon nitride, silicon carbon oxide, an embedded air gap, or a combination thereof. A capping material may be deposited and etched back to form the first capping layer 36.

Portions of the inter-level dielectric layers 34 may be cut while the first capping layer 36 is formed. As a result, the first edge portion of each of the horizontal layers 14B may be exposed.

While the first capping layer 36 is formed or after the first capping layer 36 is formed, the first hole-type vertical openings 32 may be expanded.

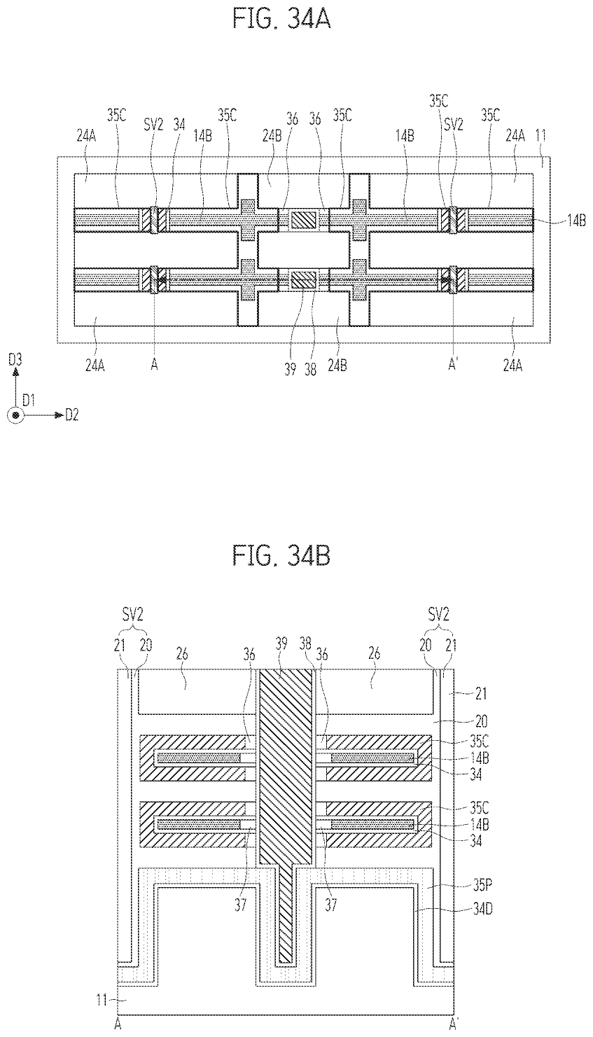

FIG. 34A is a plan view illustrating a method for forming a vertical conductive line 39, and FIG. 34B is a cross-sectional view taken along a line A-A′ shown in FIG. 34A. FIG. 34A may be a plan view of the horizontal conductive layer 35C level illustrating a method for forming the vertical conductive line 39.

Referring to FIGS. 34A and 34B, a vertical conductive line 39 coupled to a first edge portion of each of the horizontal layers 14B may be formed. The vertical conductive line 39 may fill the first hole-type vertical openings 32. The vertical conductive line 39 may be commonly coupled to the horizontal layers 14B that are arranged in the first direction D1. The vertical conductive line 39 may include titanium nitride, tungsten, or a combination thereof. The vertical conductive line 39 may be referred to as a bit line or a vertical bit line.

Before the vertical conductive line 39 is formed, a first doped region 37 and a first contact node 38 may be formed. A first doped region 37 may be formed in the first edge portions of the horizontal layers 14B. Forming the first doped region 37 may include depositing polysilicon that is doped with an N-type impurity, performing a heat treatment, and removing the doped polysilicon. The first doped region 37 may include an impurity diffused from the doped polysilicon. According to another embodiment of the present invention, the first doped region 37 may be formed by a doping process of an impurity.

The second contact node 38 may include doped polysilicon. The first doped region 37 may include an impurity diffused from a second contact node 38.

The vertical conductive line 39 may correspond to the first conductive line BL as illustrated in FIGS. 1A to 1D.

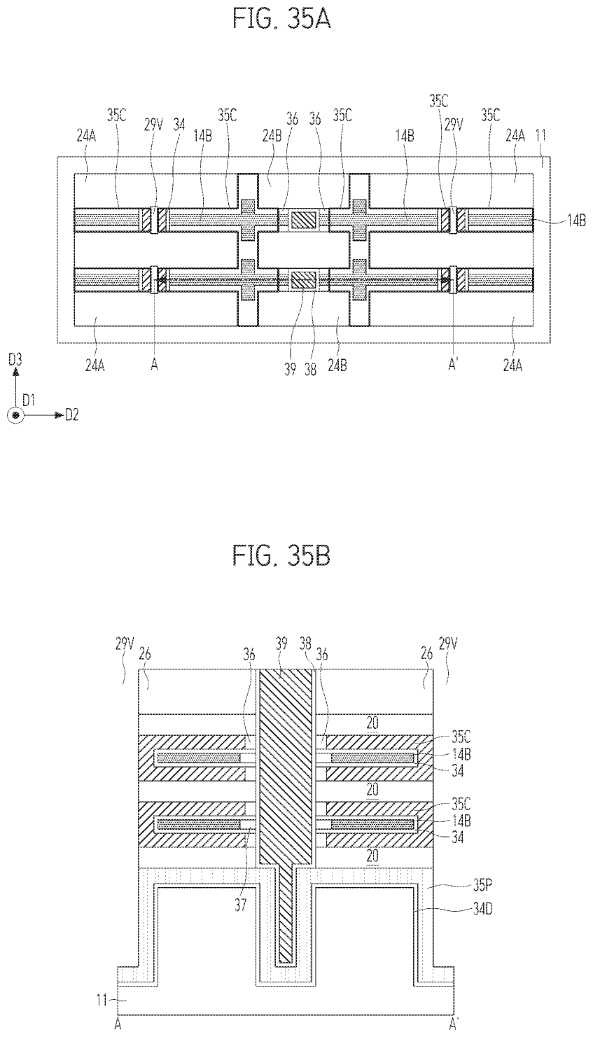

FIG. 35A is a plan view illustrating a method for forming the preliminary second hole-type vertical openings 29V, and FIG. 35B is a cross-sectional view taken along a line A-A′ shown in FIG. 35A. FIG. 35A may be a plan view of the horizontal conductive layer 35C level illustrating a method for forming the preliminary second hole-type vertical openings 29V.

Referring to FIGS. 35A and 35B, in order to form the preliminary second hole-type vertical openings 29V, a portion of the second sacrificial pillar structure SV2 may be removed. First side surfaces of the horizontal conductive layers 35C may be exposed by the preliminary second hole-type vertical openings 29V, and the second dielectric layers 20 may be cut.

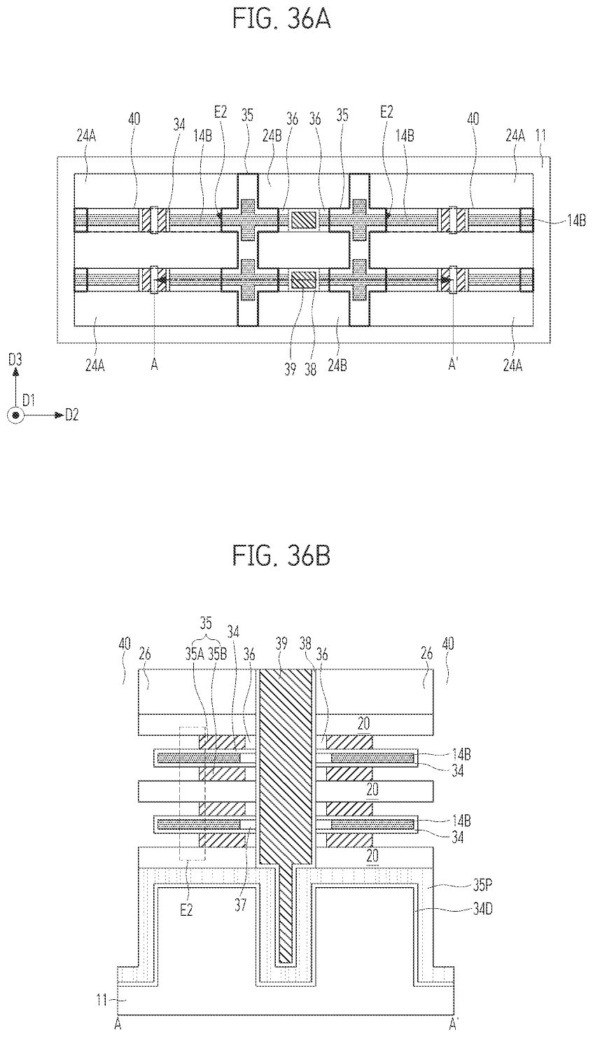

FIG. 36A is a plan view illustrating a method for forming the horizontal conductive lines 35, and FIG. 36B is a cross-sectional view taken along a line A-A′ shown in FIG. 36A.

Referring to FIGS. 36A and 36B, second side surfaces of the horizontal conductive layer pattern 35C may be selectively recessed through the preliminary second hole-type vertical openings 29V. As a result, a horizontal conductive line 35 may be formed.

The horizontal conductive line 35 may include a pair of first and second horizontal conductive lines 35A and 35B that are facing each other with the horizontal layer 14B therebetween. The first and second horizontal conductive lines 35A and 35B may include a metal-based material, a semiconductor material, or a combination thereof. The first and second horizontal conductive lines 35A and 35B may include titanium nitride, tungsten, polysilicon, or a combination thereof. For example, the first and second horizontal conductive lines 35A and 35B may include a TiN/W stack in which titanium nitride and tungsten are sequentially stacked. The first and second horizontal conductive lines 35A and 35B may include an N-type work function material or a P-type work function material. The N-type work function material may have a low work function of approximately 4.5 eV or less, and the P-type work function material may have a high work function of approximately 4.5 eV or more.

The horizontal conductive line 35 may correspond to the second conductive line DWL as illustrated in FIGS. 1A to 1D, and the first and second horizontal conductive lines 35A and 35B may correspond to the upper horizontal line G1 and the lower horizontal line G2. Referring to FIGS. 1A to 1D, each of the first and second horizontal conductive lines 35A and 35B may have a cross shape, and each of the first and second horizontal conductive lines 35A and 35B may include a channel overlapping portion WLP and channel non-overlapping portions NOL.

As described above with reference to a series of the processes, forming the horizontal conductive line 35 may include forming the inter-level dielectric layer 34 that covers the surface of the preliminary horizontal layer 14B, forming a horizontal conductive layer 35C that surrounds the preliminary horizontal layer 14B over the inter-level dielectric layer 34, and performing a first side recess process and a second side recess process onto the horizontal conductive layer 35C. A first edge portion (refer to ‘E1’ of FIGS. 31 and 32C) of the horizontal conductive line 35 may be defined by the first side recess process, and a second edge portion (refer to ‘E2’ in FIGS. 36A and 36B) of the horizontal conductive line 35 may be defined by the second side recess process.

Since the first side recess process and the second side recess process are used to form the horizontal conductive line 35, the gate oxide intensity (GOI) characteristics of the inter-level dielectric layer 34 may be improved. The thickness of the inter-level dielectric layer 34 may be maintained uniformly.

According to another embodiment of the present invention, the first and second horizontal conductive lines 35A and 35B of the horizontal conductive line 35 may have a triple work function electrode structure. Accordingly, it is possible to improve Gate-Induced Drain Leakage (GIDL).

After the horizontal conductive line 35 is formed, the preliminary second hole-type vertical openings may be enlarged as indicated by a reference numeral ‘40’. Hereinafter, the expanded preliminary second hole-type vertical openings may be simply referred to as second hole-type vertical openings 40.

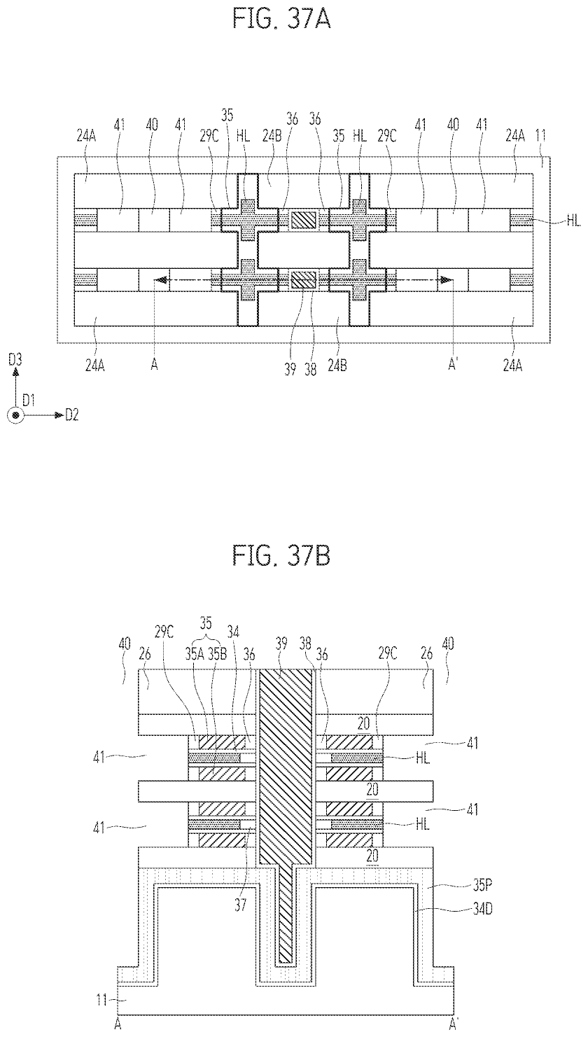

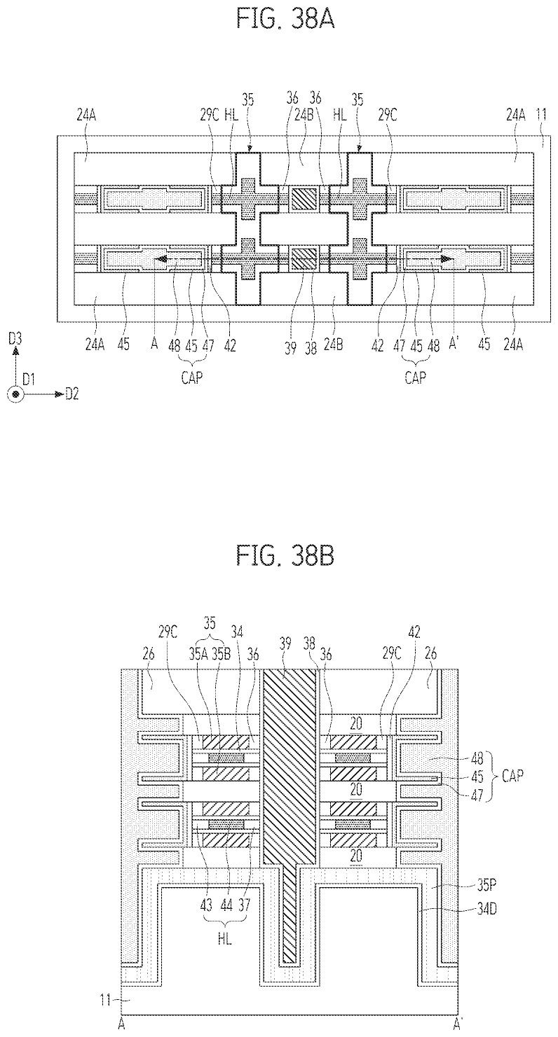

FIG. 37A is a plan view illustrating a method for forming the storage openings 41, and FIG. 37B is a cross-sectional view taken along a line A-A′ shown in FIG. 38A.

Referring to FIGS. 37A and 37B, in order to form the second capping layers 29C, a capping material may be deposited and etched. The second capping layers 29C may include silicon oxide, silicon nitride, or a combination thereof.

After the second capping layers 29C are formed, the inter-level dielectric layers 34 may be laterally (e.g., horizontally) recessed in the second direction D2. Subsequently, the second edge portions of the horizontal layers 14B may be horizontally recessed in the second direction D2. As a result, the horizontal layers may remain as indicated by a reference symbol ‘HL’.

The horizontal layers HL may include a first edge and a second edge. The first edge may refer to a portion that is coupled to the first contact node 38 and the vertical conductive line 39, and the second edge may refer to a portion that is exposed by the storage openings 41.

The storage openings 41 may be disposed between the second dielectric layers 20. The second capping layers 29C may be disposed on the lower and upper portions of the horizontal layers HL, individually.

As described above, as the second capping layer 29C and the horizontal layer HL are formed, the storage openings 41 extending laterally, e.g., horizontally from the second hole-type vertical openings 40 may be formed. The storage openings 41 may be referred to as capacitor openings.

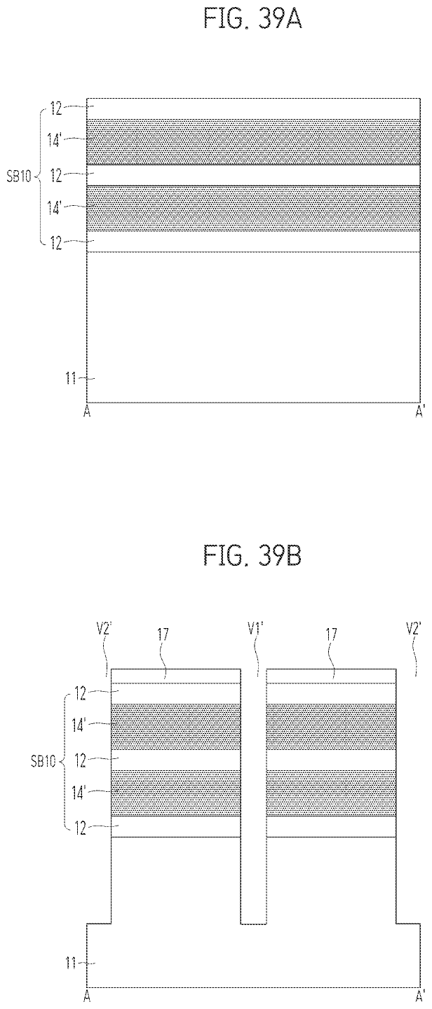

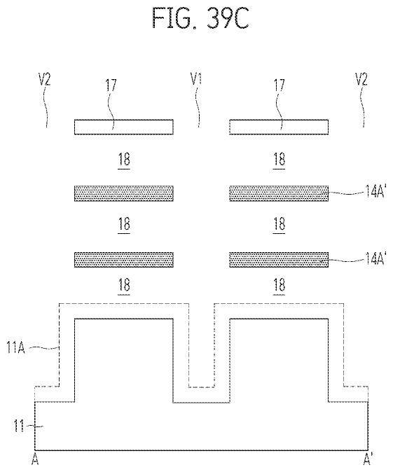

FIG. 38A is a plan view illustrating a method for forming the second contact node 38 and the data storage element CAP, and FIG. 38B is a cross-sectional view taken along a line A-A′ shown in FIG. 39A. As for detailed description on the method for forming the second contact node 38 and the data storage element CAP, FIGS. 23A to 26B may be referred to.

Referring to FIGS. 38A and 38B, a second doped region 43 may be formed in the second edge of the horizontal layer HL. Forming the second doped region 43 may include depositing polysilicon that is doped with an N-type impurity, performing a heat treatment, and removing the doped polysilicon. The second doped region 43 may include an impurity diffused from the doped polysilicon. According to another embodiment of the present invention, the doped polysilicon may remain after the heat treatment.

Subsequently, a second contact node 42 may be formed over the second edge of the horizontal layer HL. The second contact node 42 may include doped polysilicon. The second doped region 43 may include an impurity diffused from the second contact node 42.

The horizontal layer HL may include a first doped region 37, a second doped region 43, and a channel 44 that are laterally, e.g., horizontally disposed in the second direction D2. The channel 44 may be defined between the first doped region 37 and the second doped region 43. The channel 44 may vertically overlap with the horizontal conductive line 35. As illustrated in FIGS. 1A to 1C, the horizontal layer HL may have a cross shape, and the channel 44 may also have a cross shape.

Subsequently, the first electrode 45 of the data storage element may be formed over the second contact node 42. The first electrode 45 may have a horizontally oriented cylindrical shape.

Subsequently, referring to FIGS. 25A and 25B, the second dielectric layers 20 may be laterally (e.g., horizontally) recessed (refer to a reference numeral 46). As a result, the outer surfaces of the first electrode 45 may be exposed.

Subsequently, a dielectric layer 47 and a second electrode 48 may be sequentially formed over the first electrodes 45. The first electrode 45, the dielectric layer 47, and the second electrode 48 may become a data storage element CAP.

According to the description with reference to FIGS. 27A to 38B, a method for fabricating a semiconductor device in accordance with another embodiment of the present invention may include forming preliminary horizontal layers 14A vertically stacked in the first direction D1 over the lower structure 11 and extending laterally (e.g., horizontally) in the second direction D2 crossing the first direction D1, forming conductive target layers disposed in the upper and lower portions of each of the preliminary horizontal layers 14A, forming horizontal layers 14B by trimming the preliminary horizontal layers 14A in the third direction D3 crossing the second direction D2, forming trimmed conductive target layers by trimming the conductive target layers in the third direction D3, and forming a pair of horizontal conductive lines 35 respectively disposed in the upper and lower surfaces of the horizontal layers 14B by horizontally recessing the edge portions on both sides of each of the trimmed conductive target layers in the second direction D2. The conductive target layers may correspond to the horizontal conductive layers 35C as illustrated in FIGS. 27A to 27C. The trimmed conductive target layer may correspond to the trimmed horizontal conductive layers 35C as illustrated in FIGS. 29A and 29B.

FIGS. 39A to 39C are cross-sectional views illustrating a method for fabricating a semiconductor device in accordance with another embodiment of the present invention.

Referring to FIG. 39A, a stack body SB10 may be formed over the lower structure 11. The stack body SB10 may include an alternating stack of first semiconductor layers and second semiconductor layers. For example, in the alternating stack, a plurality of silicon germanium layers 12 and a plurality of monocrystalline silicon layers 14′ may be alternately stacked by an epitaxial growth process. The silicon germanium layers 12 may be sacrificial layers, and the monocrystalline silicon layers 14′ may be recess target layers. The silicon germanium layers 12 may correspond to the first layers 12A or the third layers 12B of FIG. 4B, and the monocrystalline silicon layers 14′ may correspond to the fourth layers 14 of FIG. 4B. Unlike the stack body SB of FIG. 4B, the stack body SB10 may be formed of alternating stacks of the silicon germanium layers 12 and the monocrystalline silicon layers 14′.

Subsequently, a series of the processes as illustrated in FIGS. 4A to 5C may be performed. For example, sacrificial isolation openings 15A and 15B and sacrificial isolation layers 16A and 16B may be formed in the stack body SB10.

Subsequently, referring to FIG. 39B, a hard mask layer pattern 17 may be formed over the stack body SB10.

Subsequently, the stack body SB may be etched by using the hard mask layer pattern 17 as an etch barrier. As a result, a plurality of first and second sacrificial vertical openings V1′ and V2′ may be formed in the stack body SB10.

Referring to FIG. 39C, preliminary horizontal layers 14A′ and horizontal recesses 18 may be formed. The preliminary horizontal layers 14A′ and the horizontal recesses 18 may be formed by a recess process of the silicon germanium layers 12 and the monocrystalline silicon layers 14′ of FIG. 39B. After the silicon germanium layers 12 are removed, a recess process of the monocrystalline silicon layers 14′ may be performed. The preliminary horizontal layers 14A′ may correspond to the preliminary horizontal layers 14A of FIG. 7B.

In order to recess the silicon germanium layers 12, a wet etching process or a dry etching process may be used. The silicon germanium layers 12 may be etched by using an etchant or an etching gas having a selectivity with respect to the monocrystalline silicon layers 14′.

A recess process of the monocrystalline silicon layers 14′ for forming the preliminary horizontal layers 14A′ may use, for example, HSC1 (Hot SC-1). HSC1 may include a solution in which ammonium hydroxide (NH₄OH), hydrogen peroxide (H₂O₂) and water (H₂O) are mixed at a ratio of approximately 1:4:20. The monocrystalline silicon layers 14′ may be selectively etched by using the HSC1.

After the preliminary horizontal layers 14A′ are formed, the first and second sacrificial vertical openings may be expanded as indicated by reference symbols ‘V1’ and ‘V2’. The preliminary horizontal layers 14A′ may be spaced apart from each other by first and second sacrificial vertical openings V1 and V2 in the second direction D2. The preliminary horizontal layers 14A′ may have a shape in which a plurality of cross shapes are merged in the third direction D3. While the preliminary horizontal layers 14A′ are formed, the surface of the lower structure 11 may be recessed to a predetermined depth (refer to a reference numeral ‘11A’). As a result, the depths of the first and second sacrificial vertical openings V1 and V2 may increase.

Subsequently, a series of the processes illustrated in FIGS. 8A to 26B may be performed.

According to the embodiment of the present invention, it is possible to prevent a bridge between the vertically neighboring horizontal conductive lines when 3D memory cells are formed.

According to the embodiment of the present invention, the yield of 3D memory cells may be improved.

While the present invention has been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A method for fabricating a semiconductor device, the method comprising:
forming preliminary horizontal layers vertically stacked over a lower structure in a first direction, each preliminary horizontal layer extending in a second direction crossing the first direction;
forming trimming target layers that surround each of the preliminary horizontal layers;
forming horizontal layers by trimming the preliminary horizontal layers in a third direction crossing the second direction;
forming trimmed target layers by trimming the trimming target layers in the third direction; and
replacing the trimmed target layers with conductive layers.

2. The method of claim 1, further comprising:
after the forming of the horizontal layers,
forming spacers on side surfaces of the horizontal layers.

3. The method of claim 1, wherein a trimming depth of the preliminary horizontal layers is greater than a trimming depth of the trimming target layers.

4. The method of claim 3, wherein the trimming target layers include a dielectric material.

5. The method of claim 1, wherein the replacing the trimmed target layers with the conductive layers includes:
forming horizontal level recesses that expose portions of the horizontal layers by removing the trimmed target layers;
forming an inter-level dielectric layer over exposed portions of the horizontal layers; and
forming a conductive material that fills the horizontal level recesses over the inter-level dielectric layer.

6. The method of claim 1, wherein the forming the preliminary horizontal layers includes:
forming a stack body by alternately stacking a plurality of sacrificial layers and a plurality of recess target layers over the lower structure;
forming sacrificial vertical openings that are spaced apart from each other in the second direction by etching the stack body;
removing the sacrificial layers from the sacrificial vertical openings; and
recessing the recess target layers from the sacrificial vertical openings to form the preliminary horizontal layers.

7. The method of claim 6, wherein the sacrificial layers include a silicon germanium layer, and
the recess target layers include a monocrystalline silicon layer.

8. The method of claim 6, wherein the sacrificial layers include a stack of a silicon germanium layer and a first monocrystalline silicon layer, and
wherein the recess target layers include a second monocrystalline silicon layer, and
wherein the second monocrystalline silicon layer is formed to be thicker than the first monocrystalline silicon layer.

9. The method of claim 1, further comprising:
after the forming of the trimming target layers,
forming inter-cell dielectric layers that surround the trimming target layers.

10. A method for fabricating a semiconductor device, the method comprising:
forming preliminary horizontal layers vertically stacked over a lower structure in a first direction and extending horizontally in a second direction crossing the first direction;
forming conductive target layers disposed in upper and lower portions of each of the preliminary horizontal layers;
forming horizontal layers by trimming the preliminary horizontal layers in a third direction crossing the second direction;
forming a trimmed conductive target layer by trimming the conductive target layers in the third direction; and
forming a pair of horizontal conductive lines respectively disposed on upper and lower surfaces of the horizontal layers by horizontally recessing edge portions on both sides of the trimmed conductive target layer in the second direction.

11. The method of claim 10, further comprising:
after the forming of the horizontal layers,
forming spacers on the side surfaces of the horizontal layers.

12. The method of claim 10, wherein a trimming depth of the preliminary horizontal layers is greater than a trimming depth of the conductive target layers.

13. The method of claim 10, wherein the conductive target layers include polysilicon, a metal-based material, a work function material, or a combination thereof.

14. The method of claim 10, further comprising:
before the forming of the conductive target layers,
forming inter-level dielectric layers in upper and lower portions of each of the preliminary horizontal layers.

15. The method of claim 10, wherein the forming the preliminary horizontal layers includes:
forming a stack body by alternately stacking a plurality of sacrificial layers and a plurality of recess target layers over the lower structure;
forming sacrificial vertical openings that are spaced apart from each other in the second direction by etching the stack body;
removing the sacrificial layers from the sacrificial vertical openings; and
recessing the recess target layers from the sacrificial vertical openings to form the preliminary horizontal layers.

16. The method of claim 15, wherein the sacrificial layers include a silicon germanium layer, and
the recess target layers include a monocrystalline silicon layer.

17. The method of claim 15, wherein the sacrificial layers include a stack of a silicon germanium layer and a first monocrystalline silicon layer, and
wherein the recess target layers include a second monocrystalline silicon layer, and
wherein the second monocrystalline silicon layer is formed to be thicker than the first monocrystalline silicon layer.

18. The method of claim 10, wherein in the forming of the conductive target layers disposed in the upper and lower portions of each of the preliminary horizontal layers,
the conductive target layers surround the preliminary horizontal layers in the second direction.

19. The method of claim 10, wherein the forming the preliminary horizontal layers includes:
forming a stack body by alternately stacking a plurality of sacrificial layers and a plurality of recess target layers over the lower structure;
forming sacrificial isolation layers that are spaced apart from each other in the third direction by etching the stack body;
forming sacrificial vertical openings that are spaced apart from each other in the second direction by etching the stack body;
removing the sacrificial layers from the sacrificial vertical openings;
recessing the recess target layers from the sacrificial vertical openings to form the preliminary horizontal layers; and
forming cell isolation openings that are spaced apart from each other in the third direction to expose expected trimming portions of the conductive target layers by removing the sacrificial isolation layers.

20. The method of claim 10, further comprising:
after the forming of the horizontal conductive line,
forming a vertical conductive line that is commonly coupled to first edges of the horizontal layers; and
forming a data storage element that is coupled to each of the second edges of the horizontal layers.
